(19) United States
(12) Patent Application Publication
(10) Pub. No.: US 2024/0421151 A1
(43) Pub. Date: Dec. 19, 2024

(54) VERTICAL JUNCTION FIELD-EFFECT TRANSISTORS WITH SOURCE-DRAIN DIODE CELLS INTEGRATED AT DIE LEVEL

(71) Applicant: Qorvo US, Inc., Greensboro, NC (US)

(72) Inventors: Zhongda Li, Chestnut Hill, MA (US); Pete Losee, Clifton Park, NY (US); Ke Zhu, Princeton, NJ (US); Anup Bhalla, Princeton, NJ (US)

(21) Appl. No.: 18/742,386

(22) Filed: Jun. 13, 2024

Related U.S. Application Data
(60) Provisional application No. 63/507,752, filed on Jun. 13, 2023.

(51) Int. Cl. H01L 27/06; H01L 21/82; H01L 21/8252; H01L 21/8256; H01L 29/06; H01L 29/16; H01L 29/20; H01L 29/24; H01L 29/808; H01L 29/861

(52) U.S. Cl. CPC H01L 27/0629; H01L 21/8206; H01L 21/8213; H01L 21/8252; H01L 21/8256; H01L 29/0661; H01L 29/0692; H01L 29/1602; H01L 29/1608; H01L 29/2003; H01L 29/24; H01L 29/8083; H01L 29/8613

(57) ABSTRACT

This disclosure relates to a semiconductor die and a method for fabrication of a semiconductor die. The disclosed semiconductor die comprises a substrate having a drain-cathode region, a plurality of trenches and mesas, a first anode trench, and a first floating closed loop mesa surrounding the first anode trench. The semiconductor die further comprises a first anode region under the first anode trench, a plurality of source regions extending from top surfaces into the plurality of mesas, and a plurality of gate regions extending along a bottom surface and portions of sidewalls of each of the plurality of trenches. The first floating closed loop mesa electrically isolates the first anode region from the plurality of gate regions, and the first anode region electrically couples to the plurality of source regions to integrate an anti-parallel diode cell within vertical junction field-effect transistors (JFETs).

### RELATED APPLICATIONS

This application claims the benefit of provisional patent application Ser. No. 63/507,752, filed Jun. 13, 2023, the disclosure of which is hereby incorporated herein by reference in its entirety.

### FIELD OF THE DISCLOSURE

The present disclosure relates generally to semiconductor technology and in particular to an integration of anti-parallel diode cells within vertical junction field-effect transistors (JFETs) at die level.

### BACKGROUND

Vertical junction field-effect transistors (JFETs) built on silicon carbide (SiC) are of great interest for high-power conversion applications and power electronic circuits including but not limited to power factor correction circuits, DC-DC converters, DC-AC inverters, and motor drives. In this regard, there is a general need to improve the performance of vertical JFETs through a die-level integration of source-drain anti-parallel diode cells into vertical JFETs.

### SUMMARY

This disclosure relates to a semiconductor die and a method for designing semiconductor dies, wherein the semiconductor dies are trench gate vertical junction field-effect transistors (JFETs) with integrated source-drain anti-parallel diode cells at a die level. In one aspect, the disclosed semiconductor die comprises a substrate having a top surface and a bottom surface, a drain-cathode region extending from the back surface into the substrate, a plurality of trenches, wherein each of the plurality of trenches extends from the top surface into the substrate, and a plurality of mesas, wherein each of the plurality of the mesas resides between adjacent ones of the plurality of trenches. The semiconductor die further comprises a first anode trench extending from the top surface into the substrate forming a contiguous region to a first two or more of the plurality of trenches, a first floating closed loop mesa surrounding the first anode trench and in between a first two or more of the plurality of mesas, a first anode region under the first anode trench, a plurality of source regions, wherein each of the plurality of source regions extends from a top surface into each of the plurality of mesas, and a plurality of gate regions, wherein each of the plurality of gate regions extends along a bottom surface and portions of sidewalls of each of the plurality of trenches. The first floating closed loop mesa electrically isolates the first anode region from the plurality of gate regions, and the first anode region and the plurality of source regions are electrically coupled to form a first anti-parallel diode cell integrated within the vertical JFETs.

In an embodiment, the semiconductor die further comprises a first floating source region extending from a top surface into the first floating closed loop mesa, and a first floating source ohmic contact at least partially over a top surface of the first floating source region.

In an embodiment, the semiconductor die further comprises a plurality of gate ohmic contacts at least partially over the plurality of gate regions at the bottom surfaces of the plurality of trenches, a first anode ohmic contact at least partially over a top surface of the first anode region, and a plurality of source ohmic contacts at least partially over the top surfaces of the plurality of source regions.

In an embodiment, the semiconductor die further comprises an interlayer dielectric filling the plurality of trenches and the first anode trench and covering surfaces of the first floating closed loop mesa to electrically isolate the first anode region from the plurality of gate regions.

In an embodiment, the semiconductor die further comprises a first via hole in the interlayer dielectric in the first anode trench.

In an embodiment, the semiconductor die further comprises a source overlay metal over and electrically coupled to the plurality of source ohmic contacts and in the first via hole and electrically coupled to the first anode ohmic contact.

In an embodiment, the semiconductor die further comprises a gate overlay metal electrically coupled to the plurality of gate ohmic contacts.

In an embodiment, the semiconductor die further comprises a drain-cathode electrode over the bottom surface of the substrate and electrically coupled to the drain-cathode region.

In an embodiment, the semiconductor die further comprises a second anode trench extending from the top surface into the substrate forming a contiguous region to a second two or more of the plurality of trenches, a second floating closed loop mesa surrounding the second anode trench and in between a second two or more of the plurality of mesas, and a second anode region under the second anode trench. The second floating closed loop mesa electrically isolates the second anode region from the plurality of gate regions, and the second anode region and the plurality of source regions are electrically coupled to form a second anti-parallel diode cell integrated within vertical JFETs.

In an embodiment, the semiconductor die further comprises a first floating source region extending from a top surface into the first floating closed loop mesa, a second floating source region extending from a top surface into the second floating closed loop mesa, a first floating source ohmic contact at least partially over a top surface of the first floating source region, and a second floating source ohmic contact at least partially over a top surface of the second floating source region.

In an embodiment, the semiconductor die further comprises a plurality of gate ohmic contacts at least partially over the plurality of gate regions at the bottom surfaces of the plurality of trenches, a first anode ohmic contact at least partially over a top surface of the first anode region, a second anode ohmic contact at least partially over a top surface of the second anode region, and a plurality of source ohmic contacts at least partially over the top surfaces of the plurality of source regions.

In an embodiment, the semiconductor die further comprises an interlayer dielectric filling the plurality of trenches, the first anode trench, and the second anode trench as well as covering surfaces of the first floating closed loop mesa to electrically isolate the first anode region from the plurality of gate regions as well as covering surfaces of the second floating closed loop mesa to electrically isolate the second anode region from the plurality of gate regions.

In an embodiment, the semiconductor die further comprises a first via hole in the interlayer dielectric in the first anode trench and a second via hole in the interlayer dielectric in the second anode trench.

In an embodiment, the semiconductor die further comprises a source overlay metal over and electrically coupled to the plurality of source ohmic contacts, in the first via hole to electrically couple to the first anode ohmic contact, and in the second via hole to electrically couple to the second anode ohmic contact.

In an embodiment, the semiconductor die further comprises a gate overlay metal electrically coupled to the plurality of gate ohmic contacts.

In an embodiment, the semiconductor die further comprises a drain-cathode electrode over the bottom surface of the substrate and electrically coupled to the drain-cathode region.

In an embodiment, the semiconductor die further comprises a third floating closed loop mesa over the top surface of the substrate surrounding the first floating closed loop mesa and a first floating trench between the third floating closed loop mesa and the first floating closed loop mesa.

In an embodiment, the semiconductor die further comprises a first floating source region extending from a top surface into the first floating closed loop mesa and a third floating source region extending from a top surface into the third floating closed loop mesa, and a first floating gate region extending along a bottom surface and portions of sidewalls of the first floating trench.

In an embodiment, the semiconductor die further comprises a first floating source ohmic contact at least partially over a top surface of the first floating source region, a third floating source ohmic contact at least partially over a top surface of the second floating source region, and a floating gate ohmic contact at least partially over a top surface of the first floating gate region.

In an embodiment, the semiconductor die further comprises a plurality of gate ohmic contacts at least partially over the plurality of gate regions at the bottom surfaces of the plurality of trenches, a first anode ohmic contact at least partially over a top surface of the first anode region, and a plurality of source ohmic contacts at least partially over the top surfaces of the plurality of source regions.

In an embodiment, the semiconductor die further comprises an interlayer dielectric filling the plurality of trenches, the first floating trench, and the first anode trench as well as covering surfaces of the first floating closed loop mesa and the third floating closed loop mesa to electrically isolate the first anode region from the plurality of gate regions.

In an embodiment, the semiconductor die further comprises a first via hole in the interlayer dielectric in the first anode trench.

In an embodiment, the semiconductor die further comprises a source overlay metal over and electrically coupled to the plurality of source ohmic contacts and in the first via hole and electrically coupled to the first anode ohmic contact.

In an embodiment, the semiconductor die further comprises a gate overlay metal electrically coupled to the plurality of gate ohmic contacts.

In an embodiment, the semiconductor die further comprises a drain-cathode electrode over the bottom surface of the substrate and electrically coupled to the drain-cathode region.

In an embodiment, the substrate comprises silicon carbide.

In an embodiment, the substrate comprises gallium nitride (GaN), aluminum nitride (AlN), gallium (III) oxide (Ga₂O₃), or diamond.

In an embodiment, the first anode trench and the plurality of trenches have the same depth.

In an embodiment, the first anode trench is deeper than each of the plurality of trenches.

In an embodiment, the bottom surfaces of the first anode trench and the plurality of trenches have the same surface area.

In an embodiment, the bottom surface of the first anode trench has a larger surface area than bottom surfaces of each of the plurality of trenches.

In an embodiment, the gate regions and the first anode region are doped with a p-type dopant, and a remaining portion of the body region and the substrate are doped with an n-type dopant.

In an embodiment, the gate regions and the first anode region are doped with an n-type dopant, and a remaining portion of the body region and the substrate are doped with a p-type dopant.

In another aspect, a method of fabricating a semiconductor die is disclosed, the method comprising providing a substrate having a top surface and a bottom surface, forming a drain-cathode region extending from the back surface into the substrate, forming a plurality of trenches, wherein each of the plurality of trenches extends from the top surface into the substrate, and forming a plurality of mesas, wherein each of the plurality of the mesas resides between adjacent ones of the plurality of trenches. The method disclosed further comprises forming a first anode trench extending from the top surface into the substrate and contiguous to a first two or more of the plurality of trenches, forming a first floating closed loop mesa surrounding the first anode trench and in between a first two or more of the plurality of mesas, forming a first anode region under the first anode trench, forming a plurality of source regions, wherein each of the plurality of source regions extends from a top surface into each of the plurality of mesas, and forming a plurality of gate regions, wherein each of the plurality of gate regions extends along a bottom surface and portions of sidewalls of each of the plurality of trenches. According to the method disclosed, the first floating closed loop mesa electrically isolates the first anode region from the plurality of gate regions, and the first anode region and the plurality of source regions are electrically coupled to form a first anti-parallel diode cell integrated within vertical JFETs.

According to the method disclosed, a first anode region forms under at least a bottom surface of the first anode trench, source regions extend into top surfaces of mesas, and gate regions that are U-shaped form beneath bottom surfaces and behind sidewalls of the of the plurality of trenches, wherein the source regions and the first anode region are electrically coupled to form a first anti-parallel diode cell integrated within JFET stripe cells.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a top view illustrating a semiconductor die having a source-drain anti-parallel diode cell integrated within vertical junction field-effect transistors (JFETs) at a die level;

FIG. 2 is an exemplary cross-sectional view illustrating a semiconductor die as shown in FIG. 1 along a line;

FIG. 3 is an exemplary cross-sectional view illustrating a semiconductor die as shown in FIG. 1 along a different line;

FIG. 4 is a top view illustrating a semiconductor die having a first and a second source-drain anti-parallel diode cell integrated within vertical JFETs at a die level;

FIG. 5 is a top view illustrating a semiconductor die having a source-drain anti-parallel diode cell with a first floating closed loop mesa and a second floating closed loop mesa integrated within vertical JFETs at a die level;

FIG. 6 is an exemplary cross-sectional view illustrating a semiconductor die having a source-drain anti-parallel diode cell integrated within vertical JFETs at a die level and according to an embodiment of the present disclosure;

FIGS. 7A-12A are cross-sectional views illustrating a semiconductor die as shown in FIG. 1 along a line through various stages of fabrication;

FIGS. 7B-12B are cross-sectional views illustrating a semiconductor die as shown in FIG. 1 along a different line through various stages of fabrication;

FIG. 7A illustrates a cross-sectional view of a substrate as used in a fabrication of a semiconductor die as shown in FIG. 1 along a line;

FIG. 7B illustrates a cross-sectional view of a substrate as used in a fabrication of a semiconductor die as shown in FIG. 1 along a different line;

FIG. 8A illustrates a cross-sectional view of a substrate as seen after trenches and an anode trench are etched as part of a fabrication process of a semiconductor die in FIG. 1 along a line;

FIG. 8B illustrates a cross-sectional view of a substrate as seen after trenches and a gate trench are etched as part of a fabrication process of a semiconductor die in FIG. 1 along a different line;

FIG. 9A illustrates a cross-sectional view of a substrate as seen after implantations of the first doping type as part of a fabrication process of a semiconductor die in FIG. 1 along a line;

FIG. 9B illustrates a cross-sectional view of a substrate as seen after implantations of the first doping type as part of a fabrication process of a semiconductor die in FIG. 1 along a different line;

FIG. 10A illustrates a cross-sectional view of a substrate as seen after self-aligned silicide contacts formation as part of a fabrication process of a semiconductor die in FIG. 1 along a line;

FIG. 10B illustrates a cross-sectional view of a substrate as seen after self-aligned silicide contacts formation as part of a fabrication process of a semiconductor die in FIG. 1 along a different line;

FIG. 11A illustrates a cross-sectional view of a substrate as seen after contact window opening using a mask as part of a fabrication process of the semiconductor die in FIG. 1 along a line;

FIG. 11B illustrates a cross-sectional view of a substrate as seen after contact window opening using a mask as part of a fabrication process of a semiconductor die in FIG. 1 along a different line;

FIG. 12A illustrates a cross-sectional view of a substrate as seen after an overlay metal is deposited as part of a fabrication process of the semiconductor die in FIG. 1 along a line; and

FIG. 12B illustrates a cross-sectional view of a substrate as seen after an overlay metal is deposited using a mask as part of a fabrication process of a semiconductor die in FIG. 1 along a different line.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

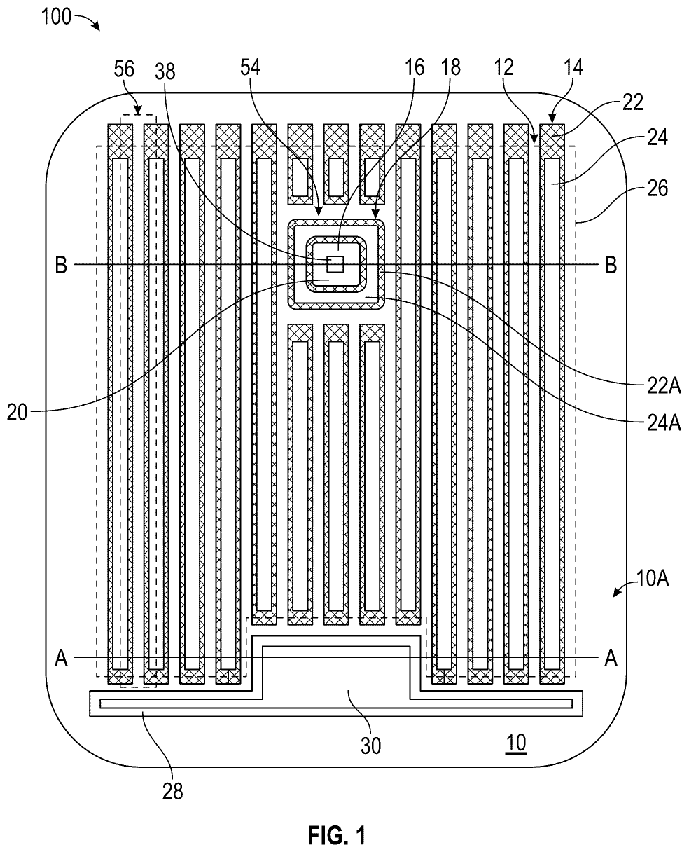

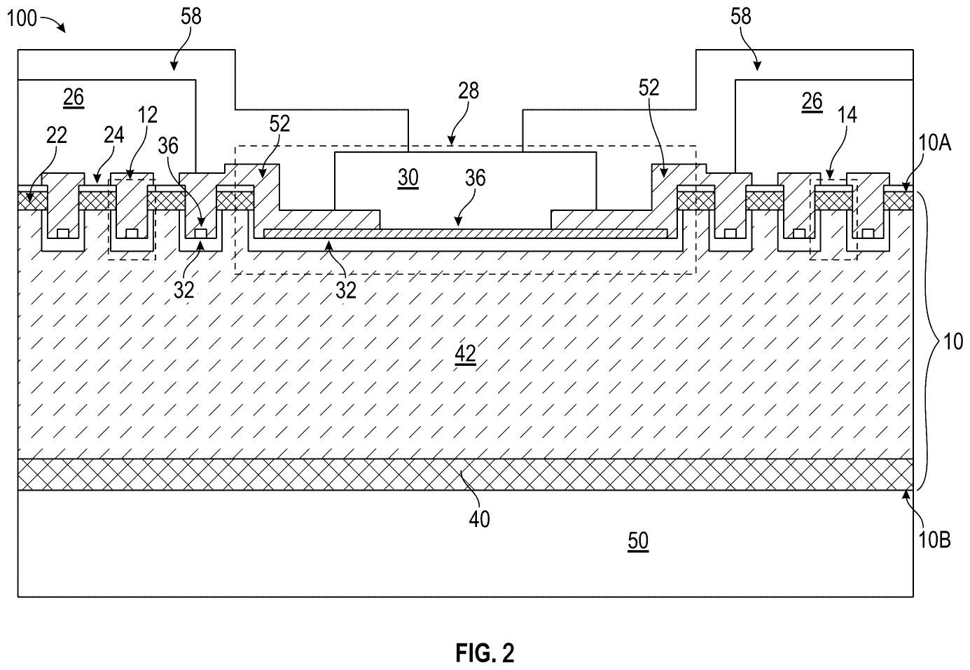

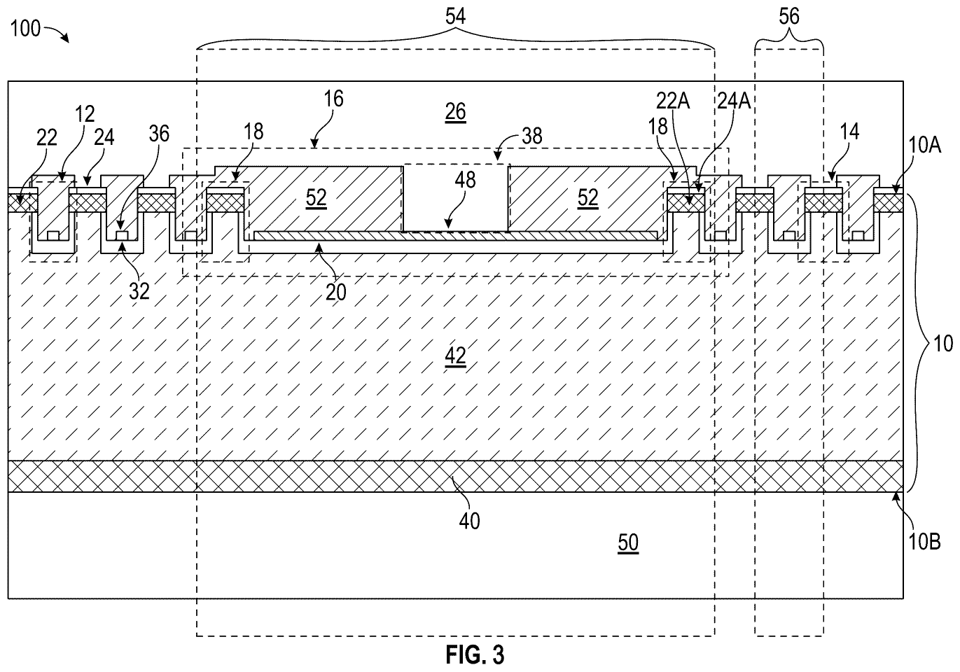

FIGS. 1, 2, and 3 illustrate top and cross-sectional views of a semiconductor die 100. In a manner described jointly with FIGS. 2 and 3, FIG. 1 and the description associated with FIGS. 1, 2, and 3 illustrate an integration of a source-drain anti-parallel diode cell 54 within vertical junction field-effect transistors (JFETs) 56 as part of the semiconductor die 100. In this regard, FIG. 1 provides a top view illustration of the semiconductor die 100. The top view illustration of FIG. 1 is better understood when viewed in conjunction with illustrations of cross-sections of the semiconductor die 100 along a line A-A and a line B-B as provided in FIGS. 2 and 3, respectively. In this regard, periodic references are made to FIG. 2 and FIG. 3 throughout the description of FIG. 1 to further describe elements of the three-dimensional semiconductor die 100 which do not appear in the plane of view provided in FIG. 1. Notwithstanding the foregoing, each of the FIGS. 2 and 3 have been described separately as part of this disclosure.

Referring first to FIG. 1, the semiconductor die 100 comprises a substrate 10, which may include silicon carbide (SiC), silicon (Si), gallium nitride (GaN), aluminum nitride (AlN), gallium oxide (Ga₂O₃), diamond, or the like. A top surface 10A of the substrate 10 is etched, leaving parallel stripe trenches, such as trench 12, (which are hereinafter collectively referred to as trenches 12) and forming parallel mesas, for example, mesa 14 (which are hereinafter collectively referred to as mesas 14). Source regions 22 that are heavily doped with a first doping type are implanted under top surfaces of the mesas 14. Source ohmic contacts 24 are deposited at least partially over top surfaces of the mesas 14 and over the source regions 22.

Not shown, but illustrated and described in more detail below in cross-sectional views of the semiconductor die 100 in FIG. 2 and FIG. 3, is a drain-cathode region 40, and a drain-cathode electrode 50. The drain-cathode region 40 extends from a bottom surface 10B of the substrate 10 into the substrate 10 and is heavily doped with the first doping type. Lastly, the drain-cathode electrode 50 is disposed over the bottom surface 10B of the substrate 10. In this application, a source overlay metal 26 couples with the source ohmic contacts 24 to form a plurality of vertical JFETs, such as the vertical JFET 56, hereinafter collectively referred to as vertical JFETs 56.

Referring to FIG. 2, an exemplary cross-sectional view of the semiconductor die 100 as shown in FIG. 1 along the line A-A is provided. The substrate 10, as described in reference to FIG. 1, further includes the drain-cathode region 40 that extends from the bottom surface 10B into the substrate 10 and is heavily doped with a first type dopant. A body region 42 forms over a top surface of the drain-cathode region 40 and is lightly doped with the first doping type and may further comprise other regions such as a drift region (not shown). The semiconductor die 100 further comprises the drain-cathode electrode 50 that is disposed over the bottom surface 10B of the substrate 10 and under the drain-cathode region 40. Also not shown in FIG. 1, but illustrated and described in more detail below in reference to FIG. 2, are gate regions 32 and gate ohmic contacts 36. The gate regions 32 extend along a bottom surface and portions of sidewalls of each of the trenches 12 by implantations of a second doping type that is the opposite type of the first doping type. The gate ohmic contacts 36 are formed over gate regions at bottom surfaces of the trenches 12. The gate ohmic contacts 36 are electrically connected to one another and to a gate overlay metal 30 that is disposed over a bottom surface of a gate contact window 28 that extends from the top surface 10A into the substrate 10 to form a trench, for example, by etching. In this manner, the gate region 32 forms along a bottom surface and portions of sidewalls of the gate contact window 28 by implantations of the second doping type. The gate ohmic contact 36 is disposed over the bottom surface of the gate contact window 28 above the gate region 32. Furthermore, the gate overlay metal 30 is deposited at least partially over a top surface of the gate ohmic contact 36 within the gate contact window 28.

In connection therewith, FIG. 2 illustrates the trenches 12 over the top surface 10A of the substrate 10 and separated by the mesas 14. Furthermore, the source regions 22 that are heavily doped with the second doping type are shown to extend from top surfaces of the mesas 14 into the mesas 14. The source ohmic contacts 24 are deposited at least partially over top surfaces of the mesas 14. As shown in FIG. 1 along the line A-A, a portion of the top surface of the substrate 10 is etched, leaving the gate contact window 28. As illustrated in the cross-sectional view of FIG. 2, the gate contact window 28 is etched into the top surface 10A of the substrate 10 followed by a formation of the gate regions 32 under bottom surfaces and portions of sidewalls of the gate contact window 28 through a doping process using the second doping type. The gate ohmic contact 36 is disposed over the bottom surface of the gate contact window 28 above the gate region 32 followed by the deposition of the gate overlay metal 30 at least partially over a top surface of the gate ohmic contact 36 within the gate contact window 28.

FIG. 2 also illustrates a formation of the gate regions 32 under bottom surfaces and portions of sidewalls of the trenches 12 through a doping process using the second doping type. The gate ohmic contacts 36 are then deposited over bottom surfaces of the trenches 12. It is important to note that the position, shape, depth, and/or number of the trenches 12 and the gate contact window 28 may vary and be changed without departing from the scope of the present disclosure. An interlayer dielectric 52 fills the trenches 12 and the gate contact window 28. In this regard, an opening in the interlayer dielectric 52 in the gate contact window 28 forms to provide a contact path to the gate ohmic contact 36 over the bottom surface of the gate contact window 28. Therefore, the gate overlay metal 30 connects to the gate ohmic contacts 36 over bottom surfaces of the trenches 12, and the source overlay metal 26 couples with the source ohmic contacts 24 to form a plurality of the vertical JFETs 56. A passivation layer 58 may be deposited to electrically isolate the gate overlay metal 30 from the source overlay metal 26. In various embodiments, the first dopant type may be an N dopant type and the second dopant type may be a P dopant type or vice versa.

The semiconductor die 100 further comprises the source-drain anti-parallel diode cell 54 that is integrated within the vertical JFETs 56 at a die level. As described jointly with FIG. 3, FIG. 1 illustrates an integration of the source-drain anti-parallel diode cell 54 within the vertical JFETs 56 at a die level and without a need for changing a stripe cell structure of the vertical JFETs 56 to a different structure, for example, a closed loop structure. The source-drain anti-parallel diode cell 54 comprises an anode region 20 of the second doping type. In this regard, an area over the top surface 10A of the substrate 10 and in between one or more of the vertical JFETs 56 is etched, leaving an anode trench 16 and a floating closed loop mesa 18 surrounding the anode trench 16. A bottom surface of the anode trench 16 is heavily doped with the second type dopant to form the anode region 20. An anode ohmic contact 48 (as shown in FIG. 3) is deposited over the anode region 20 at a bottom surface of the anode trench 16. According to various embodiments, the anode trench 16 may be etched to have a desired shape and/or depth. The floating closed loop mesa 18 comprises a floating source region 22A that forms under a top surface of the floating closed loop mesa 18 through an implantation by dopants of a first doping type. In an embodiment, the floating source region 22A and the source regions 22 are formed as part of a single implantation process. A floating source ohmic contact 24A is deposited at least partially over a top surface of the floating source region 22A over the top surface of the floating closed loop mesa 18. Similarly, the floating source ohmic contact 24A and the source ohmic contacts 24 may be deposited simultaneously.

On this point, FIG. 3 further illustrates elements of the three-dimensional semiconductor die 100, which does not appear in the plane of view of FIG. 1 along the line B-B. In this regard, the semiconductor die 100, as shown in FIG. 3, includes the anode trench 16 formed over a portion of the top surface 10A of the substrate 10 and surrounded by two of the floating closed loop mesas 18. The floating source regions 22A form under top surfaces of the floating closed loop mesas 18. The floating source ohmic contacts 24A are then deposited at least partially over top surfaces of the floating closed loop mesas 18 and above the floating source regions 22A. It is important to note that the two floating closed loop mesas 18 form part of a unitary floating closed loop mesa 18 surrounding the anode trench 16, as shown in FIG. 1. Additionally, FIG. 3 illustrates the anode region 20 and the anode ohmic contact 48. In this regard, the bottom surface and sidewalls of the anode trench 16 are heavily doped with the second type dopant to form the anode region 20. Furthermore, the anode ohmic contact 48 is disposed over a bottom surface of the anode trench 16 and above the anode region 20. The interlayer dielectric 52 further fills the trenches 12 and the anode trench 16 and covers the floating closed loop mesas 18 adjacent to the anode trench 16. In this regard, the interlayer dielectric 52 electrically isolates the floating source ohmic contacts 24A over top surfaces of the floating closed loop mesas 18 from contacting the source overlay metal 26. An opening, for example, a via 38, forms in the interlayer dielectric 52 in the anode trench 16 to form a connection path between the anode ohmic contact 48 and the source overlay metal 26. The interlayer dielectric 52 covering the floating closed loop mesa 18 is to electrically isolate gate regions outside of the floating closed loop mesa 18 from the anode region 20 at the bottom of the anode trench 16. Additionally, the interlayer dielectric 52 electrically isolates the floating source ohmic contact 24A from the source overlay metal 26 to render the floating source ohmic contact 24A over the top surface of the floating closed loop mesa 18, floating (i.e., non-connected).

The source overlay metal 26 is disposed over and electrically couples to the source ohmic contacts 24 over the top surfaces of the mesas 14. In an embodiment, the source overlay metal 26 fills the via 38 to form contact with and electrically couple to the anode ohmic contact 48 over the bottom surface of the anode trench 16. In this manner, the source-drain anti-parallel diode cell 54 forms within the vertical JFETs 56 and as a part of the semiconductor die 100.

Returning back now to FIG. 1, the electrical isolation of gate regions of a plurality of the vertical JFETs 56 from the anode region 20 of the source-drain anti-parallel diode cell 54 using the floating closed loop mesa 18 is advantageous as a self-enclosed diode cell, such as the source-drain anti-parallel diode cell 54, and may be integrated within a plurality of the vertical JFETs 56 without having to change the structure of the vertical JFETs 56 from the stripe cell design to a closed loop design. Therefore, a higher degree of flexibility can be exercised in selecting parameters, such as location, depth, or surface area as the source-drain anti-parallel diode cells 54 are designed to be integrated as part of the semiconductor die 100. Furthermore, the electrical isolation of the anode region 20 by the floating closed loop mesa 18 allows the source-drain anti-parallel diode cell 54 to have an anode trench 16 that extends deeper into the substrate 10 compared to the trenches 12 of vertical JFETs 56. It also enables a bottom surface of the anode trench 16 to have a larger surface area compared with the trenches 12 of the vertical JFETs 56. This is beneficial in enabling the source-drain anti-parallel diode cell 54 to have a lower breakdown voltage (BV) than the vertical JFETs 56 and in enabling the source-drain anti-parallel diode cell 54 to serve as an avalanche clamp.

In addition to above-mentioned advantages, the integration of a self-enclosed diode cell, such as the source-drain anti-parallel diode cell 54, within a plurality of the vertical JFETs 56, provides improvements directed to the operation of the semiconductor die 100, such as providing a reverse current conduction path, also known as a source-drain current conduction path or a 3rd quadrant current conduction path, with minimized reverse current conduction losses associated with the vertical JFETs 56. Other improvements include reducing a saturation current density (Jₛₐₜ) of the semiconductor die 100 while maintaining a same threshold voltage (Vₜₕ) with minimal impact on specific on-resistances (R_{ds}A) of the vertical JFETs 56.

In certain applications that are not shown here, various embodiments of the semiconductor die 100, as disclosed herein, may connect in series with a metal oxide semiconductor field-effect transistor to form a dual-gate cascode field-effect transistor (FET) configuration that is well known to those skilled in the art and is therefore not described here for the sake of brevity of the description. In this regard, the integration of the semiconductor die 100 in the dual-gate cascode FET configuration is advantageous as it reduces the on-resistance of the semiconductor die 100 and improves controlling of the switching behavior of the semiconductor die 100, leading to a reduction in energy losses. Furthermore, a reduction in saturation current density provides a longer cascode short-circuit withstand time and an improved safe operating area. In certain embodiments, by reducing a surface area or size of the gate contact window 28 and therefore the gate overlay metal 30 or by increasing a resistance associated with the gate overlay metal 30 or through inclusion of an external resistive component as a part of a conduction path to the gate overlay metal 30, a more resistive path to the gate overlay metal 30 and therefore to gate regions is formed. In this manner, in an event of a 3rd quadrant current surge, the resistive path to the gate regions encourages the 3rd quadrant current to flow through the anode region 20 of the source-drain anti-parallel diode cell 54 instead of the gate regions and therefore the gate overlay metal 30 of the vertical JFETs 56. Therefore, once the 3rd quadrant surge current in the dual-gate cascode FET configuration exceeds the vertical JFETs' 56 saturation current, the current goes through the anode region 20 of the source-drain anti-parallel diode cell 54 rather than the vertical JFETs 56 that is limited by the gate overlay metal 30, which is usually narrower compared with the source overlay metal 26.

FIG. 2 is an exemplary cross-sectional view of a semiconductor die 100 as shown in FIG. 1 along a line A-A. The exemplary cross-sectional view as provided in FIG. 2 illustrates a cross-section of the semiconductor die 100 wherein a gate overlay metal 30 is disposed at least partially over a bottom surface of a gate contact window 28. As described previously in reference to FIG. 1, the semiconductor die 100 comprises a substrate 10 having a drain-cathode region 40, a body region 42, and a source region 22. The drain-cathode region 40 forms under a bottom surface of the substrate 10 and is heavily doped with a second type dopant. The body region 42 forms over a top surface of the drain-cathode region 40 and is lightly doped with the second doping type and may further comprise other regions such as a drift region (not shown). The source region 22 forms over a top surface of the body region 42 and under a top surface of the substrate 10. The source region 22 is heavily doped with the second doping type. A plurality of trenches, such as a trench 12, hereinafter collectively referred to as the trenches 12, are created over the top surface of the substrate 10, for example, by etching. The trenches 12 are separated by mesas, such as a mesa 14, hereinafter collectively referred to as the mesas 14. In this manner, the source regions 22 form over top surfaces of the mesas 14. Source ohmic contacts 24 comprising silicide are disposed at least partially over the top surfaces of the mesas 14 and above the source regions 22.

Furthermore, a portion of the top surface of the substrate 10 is etched, leaving the gate contact window 28. In this regard, gate regions 32 form under bottom surfaces and sidewalls of the trenches 12 and the gate contact window 28 through a doping process using a first doping type that is the opposite type of the second doping type. Upon formation of the gate regions 32, gate ohmic contacts 36 that comprise silicide are deposited over bottom surfaces of the trenches 12 and the gate contact window 28.

The semiconductor die 100 further comprises a drain-cathode electrode 50 that is disposed over a bottom surface 10B of the substrate 10 and under the drain-cathode region 40. A mask may be used to fill the trenches 12 and the gate contact window 28 with an interlayer dielectric 52, such as oxide. Next, a mask may be used to pattern the gate contact windows 28 to the source ohmic contacts 24 over top surfaces of the mesas 14, except for the source ohmic contacts 24 over top surfaces of the mesas 14 that are adjacent to and form part of sidewalls of the gate contact window 28. Furthermore, the interlayer dielectric 52 that is filling the gate contact window 28 is partially removed to create an opening in the interlayer dielectric 52 such that a contact path to the gate ohmic contact 36 over the bottom surface of the gate contact window 28 is formed. A conductor, such as a metal, is deposited, patterned using the mask, and etched, leaving the source overlay metal 26 and the gate overlay metal 30 separated by the interlayer dielectric 52. The source overlay metal 26 makes contact to the source ohmic contact 24 on top of the mesas 14, and thereby to the source regions 22. The gate overlay metal 30 makes contact to the gate ohmic contact 36 and therefore to the gate region 32 at the bottom surface of the gate contact window 28. In this manner, the gate overlay metal 30 connects to the gate ohmic contacts 36 over bottom surfaces of the trenches 12, through connections which are not in the plane of the vertical cross-section of FIG. 1. In an embodiment, a passivation layer 58, for example an oxide, is deposited using a mask to fill open windows between the source overlay metal 26 over each side of the gate contact window 28 and the gate overlay metal 30. It is important to note that the passivation layer 58 and the interlayer dielectric 52 may comprise of a same material or a different material.

FIG. 3 is an exemplary cross-sectional view of a semiconductor die 100 as shown in FIG. 1 along a line B-B. The semiconductor die 100 comprises a substrate 10 wherein a drain-cathode region 40 forms over a backside surface of the substrate 10. The drain-cathode region 40 is heavily doped with a second type dopant with a drain-cathode electrode 50 disposed over a bottom surface 10B of the substrate 10 and over the drain-cathode region 40. In an embodiment, a drain-cathode ohmic contact (not shown) forms over the backside surface of the substrate 10 and therefore the backside surface of the drain-cathode region 40 before formation of the drain-cathode electrode 50. A body region 42 that is lightly doped with the second type dopant forms over a top surface of the drain region-cathode 40. The body region 42 may further comprise of other regions, such as a drift region, that are not shown here for the simplicity of the disclosure. A source region 22 forms over a top surface of the body region 42 and under a top surface of the substrate 10. The source region 22 is heavily doped with the second doping type.

A plurality of trenches, such as a trench 12, hereinafter collectively referred to as the trenches 12, are created, for example, by etching. The trenches 12 are separated by mesas, such as a mesa 14, hereinafter collectively referred to as the mesas 14. In this regard, bottom surfaces and sidewalls of the trenches 12 are doped with a first doping type that is the opposite type of the second doping type to form gate regions 32. Gate ohmic contacts 36 comprising silicide are disposed over bottom surfaces of the trenches 12 and above the gate regions 32. A gate electrode (not shown) connects to all the gate ohmic contacts 36 (e.g., through connections which are not in the plane of the vertical cross-section of FIG. 1 along the line A-A). Furthermore, source ohmic contacts 24 comprising silicide are disposed at least partially over top surfaces of the mesas 14 above the source regions 22.

The semiconductor die 100 further comprises an anode trench 16. In this regard, a portion of the top surface of the substrate 10 is etched, leaving the anode trench 16 surrounded by two floating closed loop mesas 18. It is important to note that the two floating closed loop mesas 18 form a part of a singular floating closed loop mesa 18, as shown in FIG. 1. A bottom surface and sidewalls of the anode trench 16 are heavily doped with the first type dopant to form an anode region 20. An anode ohmic contact 48 is disposed over a bottom surface of the anode trench 16 and over the anode region 20. Floating source ohmic regions 22A form under top surfaces of the floating closed loop mesas 18. Floating source ohmic contacts 24A are deposited at least partially over top surfaces of the floating closed loop mesas 18 and above the floating source ohmic regions 22A.

Next, an interlayer dielectric 52 fills the trenches 12 and the anode trench 16. Furthermore, the interlayer dielectric 52 covers the floating closed loop mesas 18 adjacent to the anode trench 16. In this regard, the interlayer dielectric 52 electrically isolates the floating source ohmic contacts 24A over top surfaces of the floating closed loop mesas 18 from a source overlay metal 26. An opening, for example, a via 38, is formed in the interlayer dielectric 52 disposed in the anode trench 16 such that a connection path is formed between the anode ohmic contact 48 and the source overlay metal 26. The source overlay metal 26 is disposed over and electrically couples to the source ohmic contacts 24 over top surfaces of the mesas 14. In an embodiment, the source overlay metal 26 fills the via 38 to form contact with and electrically couple to the anode ohmic contact 48 over the bottom surface of the anode trench 16. In this manner, a source-drain anti-parallel diode cell 54 forms within vertical JFETs 56.

In an embodiment, the surface area of the bottom surface of the anode trench 16 may be larger than those of the trenches 12. Alternatively, or in addition, the anode trench 16 may be etched at a higher etch rate and therefore form a deeper trench compared with the trenches 12 in the vertical JFETs 56. Increasing the surface area and/or depth of the anode trench 16 in relation to the trenches 12 is advantageous in that it allows the source-drain anti-parallel diode cell 54 to have a lower breakdown voltage (BV_{GD}) than the vertical JFETs 56, enabling the source-drain anti-parallel diode cell 54 to serve as an avalanche clamp.

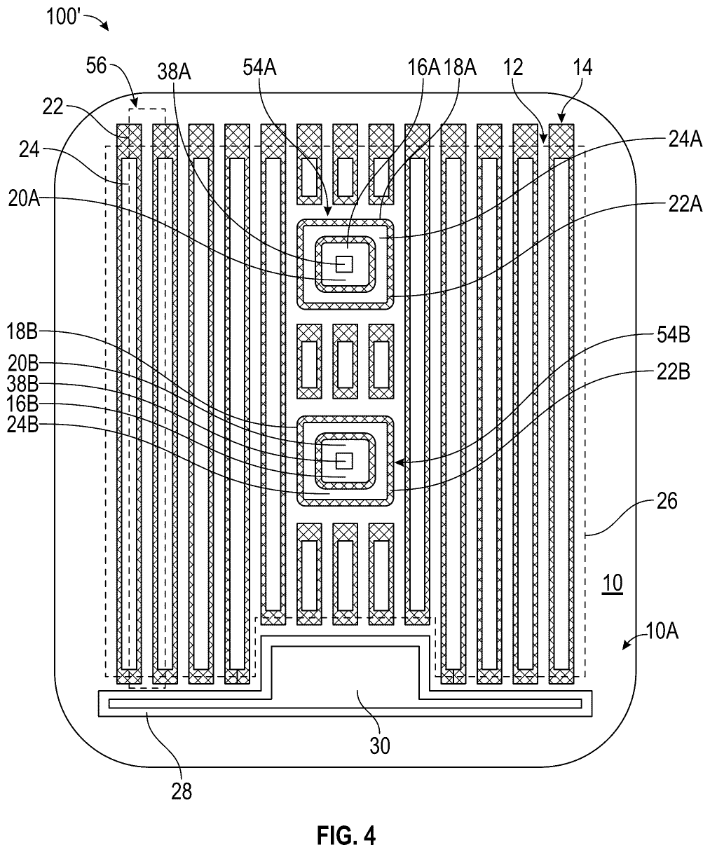

FIG. 4 is a top view illustrating a semiconductor die 100′ having a first and a second source-drain anti-parallel diode cells 54A and 54B, respectively, integrated within the vertical JFETs 56 at a die level. The semiconductor die 100′ is substantially similar to the semiconductor die 100 as shown in FIG. 1, except that rather than being limited to having only one source-drain anti-parallel diode cell 54 integrated within the vertical JFETs 56, the semiconductor die 100′ is shown as integrating the first source-drain anti-parallel diode cell 54A (hereinafter referred to as the first diode cell 54A) and the second source-drain anti-parallel diode cell 54B (hereinafter referred to as the second diode cell 54B), which are collectively referred to as diode cells 54, within the vertical JFETs 56. Other elements as previously described in reference to FIG. 1 will continue to bear the same reference numerals as shown in FIG. 1. Furthermore, it is important to note that, while only two diode cells 54 are shown to form part of the semiconductor die 100′ in FIG. 2, the same designs and methods of design are applicable to any number of a plurality of diode cells 54 having different shapes, dimensions, and trench depths and integrated in different areas over the top surface 10A of the substrate 10 within one or more of the vertical JFETs 56 of the semiconductor die 100′.

The semiconductor die 100′ comprises the substrate 10 wherein the top surface 10A of the substrate 10 is etched, leaving parallel stripe trenches, such as the trench 12, hereinafter collectively referred to as the trenches 12, and forming parallel mesas, for example, the mesa 14, hereinafter collectively referred to as the mesas 14. The source regions 22 are heavily doped with a first doping type and are implanted under top surfaces of the mesas 14. The source ohmic contacts 24 are deposited at least partially over the source regions 22.

As disclosed in reference to FIG. 1, designs and methods of designs as disclosed herein provide a degree of control and flexibility in selecting a location, a shape, dimensions, and other parameters associated with an area over the top surface 10A of the substrate 10 as part of fabrication and integration of the diode cells 54 in a desired and predetermined area in between the vertical JFETs 56. In this manner, at least a portion of one or more of the vertical JFETs 56 is replaced with the diode cells 54 without a need to change the structure of the vertical JFETs 56 from a stripe design to another design, for example, a closed loop structure. This is advantageous in that performances of both the diode cells 54 and the vertical JFETs 56 are improved while forgoing obstacles of implementing the diode cells 54 within the vertical JFETs 56 in a cost-effective and efficient manner.

Returning to FIG. 4, the gate contact window 28 is etched into the top surface 10A of the substrate 10. Not shown, but as previously illustrated and described in relation to FIGS. 1 and 2, is the formation of the gate region 32 under bottom surfaces and portions of sidewalls of the gate contact window 28 through a doping process using the second doping type. Also not shown, but as previously illustrated and described in relation to FIGS. 1 and 2, is the gate ohmic contact 36 that is disposed over the bottom surface of the gate contact window 28 above the gate region 32. The gate overlay metal 30 is then deposited at least partially over a top surface of the gate ohmic contact 36 within the gate contact window 28.

The first diode cell 54A comprises a first anode region 20A of a second doping type that is the opposite type of the first doping type. In this regard, a portion of the top surface 10A of the substrate 10 having the vertical JFETs 56 is etched, leaving a first anode trench 16A surrounded by a first floating closed loop mesa 18A. A first floating source region 22A forms under a top surface of the first floating closed loop mesa 18A through an implantation of dopants of the first doping type. A first floating source ohmic contact 24A, similar to the floating source ohmic contact 24 as shown in FIG. 1, is disposed at least partially over the top surface of the first floating closed loop mesa 18A and above the first floating source region 22A. An interlayer dielectric 52 (not shown) covers the first floating closed loop mesa 18A and fills the first anode trench 16A such that the first floating closed loop mesa 18A electrically isolates gate regions outside of the first floating closed loop mesa 18A from the first anode region 20A. Furthermore, the interlayer dielectric 52 electrically isolates the first floating source ohmic contact 24A from the source overlay metal 26 to render the first floating source ohmic contact 24A, floating (i.e., non-connected). Next, a first via 38A forms in the interlayer dielectric 52 in the first anode trench 16A to form an electrical contact path between the source overlay metal 26 and a first anode ohmic contact (not shown) disposed over a top surface of the first anode region 20A at a bottom surface of the first anode trench 16A. In this manner, the first diode cell 54A forms within a plurality of the vertical JFETs 56.

The second diode cell 54B comprises a second anode region 20B of the first doping type. In this regard, an area within the vertical JFETs 56 over the top surface of the substrate 10 is etched, leaving a second anode trench 16B isolated by a second floating closed loop mesa 18B. A second floating source region 22B forms under a top surface of the second floating closed loop mesa 18B through an implantation of dopants of the second doping type. A second floating source ohmic contact 24B is disposed at least partially over a top surface of the second floating closed loop mesa 18B and above the second floating source region 22B. An interlayer dielectric 52 (not shown) covers the second floating closed loop mesa 18B and fills the second anode trench 16B such that the second floating closed loop mesa 18B electrically isolates gate regions outside of the second floating closed loop mesa 18B from the second anode region 20B. Furthermore, the interlayer dielectric 52 electrically isolates the second floating source ohmic contact 24B from the source overlay metal 26 such that the second floating source ohmic contact 24B becomes a floating contact (i.e., non-connected contact). Next, a second via 38B forms in the interlayer dielectric 52 filling the second anode trench 16B to form an electrical contact path between the source overlay metal 26 and a second anode ohmic contact (not shown) disposed over the second anode region 20B at a bottom surface of the second anode trench 16B. In this manner, the second diode cell 54B forms within a plurality of the vertical JFETs 56.

As will be appreciated by those of skill in the art, the first anode trench 16A and the second anode trench 16B form through etching areas with shapes, surface areas, and/or depths that may be different from or similar to one another. In this regard, a number, allocation, a surface area, and a depth of each of the diode cells 54 is not limited to those shown in various embodiments of the present disclosure. It is also appreciated by those of skill in the art that a number, a spacing, and a depth of trenches of the vertical JFETs 56 is not limited to those shown in various embodiments of the present disclosure and that the principles of the present disclosure are applicable to various embodiments with a variety of the vertical JFETs 56 and/or the diode cells 54. In various embodiments, the first dopant type may be a N dopant type and the second dopant type may be a P dopant type or vice versa.

The integration of a plurality of diode cells, such as the diode cells 54, in desired and predetermined areas over and in between the vertical JFETs 56 to form the semiconductor die 100′, is advantageous in that it enables a larger surface area of the semiconductor die 100′ to be allocated to an anti-parallel diode cell that is done through formation and integration of a plurality of the diode cells 54 within the vertical JFETs 56.

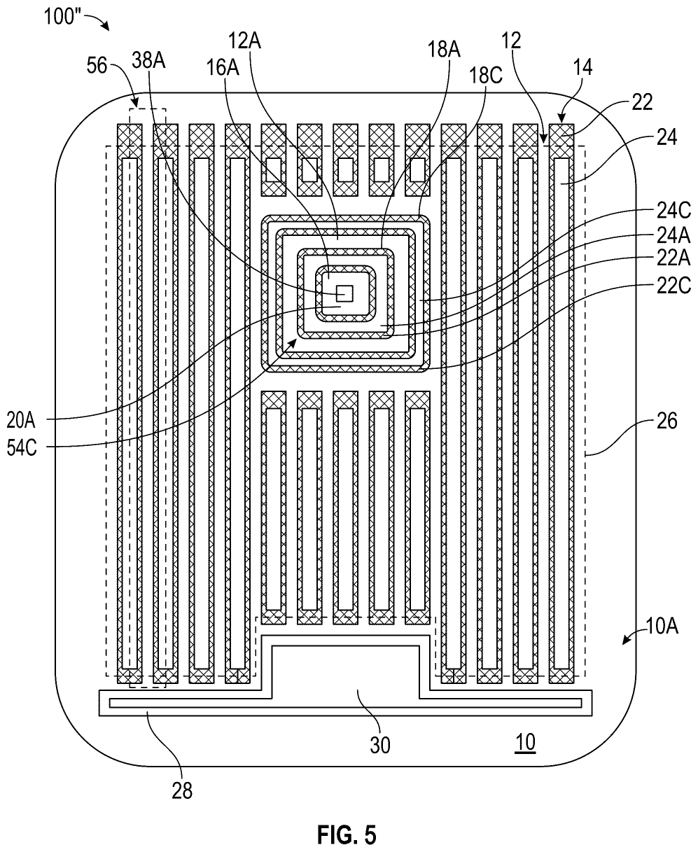

FIG. 5 is a top view illustrating a semiconductor die 100″ having a source-drain anti-parallel diode cell 54C with the first floating closed loop mesa 18A and a third floating closed loop mesa 18C integrated within the vertical JFETs 56 at a die level. The semiconductor die 100″ is substantially similar to the semiconductor die 100 as shown in FIG. 1, except that, rather than being limited to having only one floating closed loop mesa (i.e., the floating closed loop mesa 18) surrounding and isolating the diode cell 54 (as shown in FIG. 1), the semiconductor die 100″ is shown as having the source-drain anti-parallel diode cell 54C (hereinafter referred to as diode cell 54C) surrounded by the first floating closed loop mesa 18A and the third floating closed loop mesa 18C to further electrically isolate the first anode region 20A from gate regions (not shown here, but as previously illustrated and described in reference to FIGS. 1-3) of the vertical JFETs 56. In this regard, other elements as previously described in reference to FIG. 1 will continue to bear the same reference numerals as shown in FIG. 1. Furthermore, it is important to note that while only two floating closed loop mesas 18A, 18C are shown to form part of the diode cell 54C in the semiconductor die 100″, the same designs and methods of design are applicable to any number of a plurality of floating closed loop mesas isolating the diode cell 54C with different shapes, dimensions, and trench depths and integrated in different areas over the top surface 10A of the substrate 10 within one or more of the vertical JFETs 56 of the semiconductor die 100″.

The semiconductor die 100″ comprises the substrate 10 wherein the top surface 10A of the substrate 10 is etched, leaving parallel stripe trenches, such as the trench 12, hereinafter collectively referred to as the trenches 12, and forming parallel mesas, for example, the mesa 14, hereinafter collectively referred to as the mesas 14. The source regions 22 that are heavily doped with a second doping type are implanted under top surfaces of the mesas 14. The source ohmic contacts 24 are deposited at least partially over the source regions 22. In this manner, and as described above in reference to embodiments of FIGS. 1-3, a plurality of vertical JFETs, such as the vertical JFET 56, which are hereinafter collectively referred to as the vertical JFETs 56, form part of the semiconductor die 100″.

Returning to FIG. 5, the gate contact window 28 is etched into the top surface 10A of the substrate 10. Not shown but as previously illustrated and described in relation to FIGS. 1 and 2 is the formation of the gate region 32 under bottom surfaces and portions of sidewalls of the gate contact window 28 through a doping process using the second doping type. Also not shown but as previously illustrated and described in relation to FIGS. 1 and 2 is the gate ohmic contact 36 that is disposed over the bottom surface of the gate contact window 28 above the gate region 32. The gate overlay metal 30 is then deposited at least partially over a top surface of the gate ohmic contact 36 within the gate contact window 28.

Furthermore, the diode cell 54C is integrated within the vertical JFETs 56 without a need to alter the structure of the vertical JFETs 56 from a stripe cell design to a closed cell design. The diode cell 54C comprises the first anode trench 16A with the first floating closed loop mesa 18A and the third floating closed loop mesa 18C surrounding and isolating the first anode region 20A formed under the first anode trench 16A. The bottom surface of the first anode trench 16A is heavily doped with the second type dopant to form the first anode region 20A. Additionally, a floating closed loop trench 12A forms between the first floating closed loop mesa 18A and the third floating closed loop mesa 18C.

In an embodiment, a first floating source region 22A and the third floating source region 22C form under top surfaces of the first floating closed loop mesa 18A and the third floating closed loop mesa 18C, respectively. The first floating source ohmic contact 24A and a third floating source ohmic contact 24C are then deposited at least partially over top surfaces of the first floating source region 22A and the third floating source region 22C, respectively. Next, an interlayer dielectric 52 (not shown but as previously illustrated and described in reference to FIGS. 1-3) is disposed over and fills the anode trench 16A and the floating closed loop trench 12A and covers top surfaces of the first floating closed loop mesa 18A and the third floating closed loop mesa 18C. Therefore, the first floating closed loop mesa 18A, the third floating closed loop mesa 18C, and the floating closed loop trench 12A electrically isolate the anode region 20A of the diode cell 54C from gate regions of the vertical JFETs 56. Furthermore, the interlayer dielectric 52 isolates the first and third floating source ohmic contacts 24A and 24C, respectively, over top surfaces of the first floating closed loop mesa 18A and the first floating closed loop mesa 18A from the source overlay metal 26. The first via 38A forms in the interlayer dielectric 52 in the anode trench 16A to form an electrical contact path between the source overlay metal 26 and an anode ohmic contact (not shown) disposed over a top surface of the anode region 20A. In various embodiments, the first dopant type may be a N dopant type and the second dopant type may be a P dopant type or vice versa. In this manner, the diode cell 54C forms within the vertical JFETs 56.

The inclusion and integration of an additional floating closed loop mesa, such as the third floating closed loop mesa 18C, is particularly advantageous in that the third floating closed loop mesa 18C further electrically isolates the anode region 20A of the diode cell 54C from gate regions of the vertical JFETs 56. In this regard, each of the first floating closed loop mesa 18A and the third floating closed loop mesa 18C contributes to a voltage potential difference between the gate region and the anode region 20A (V_{GA}) by a value in the range of 10V to 200V, 20V to 100V, and 50V to 70V. Therefore, to turn off the normally-on vertical JFETs 56, a voltage potential difference between the gate region and the source regions 22 (V_{GS}) that is lower (more negative in value) than threshold voltage (Vₜₕ) of the vertical JFETs 56 must be applied. The increased voltage potential difference between gate region and the anode region 20A (V_{GA}) is further advantageous in that it reduces any reverse current leakage and improves the reverse breakdown voltage of the diode cell 54C. As will be appreciated by those skilled in the art, while only two floating closed loop mesas, the first floating closed loop mesa 18A and the third floating closed loop mesa 18C, form part of the semiconductor die 100″ in isolating the diode cell 54C, the principles of the present disclosure are applicable to various embodiments having more or fewer than two floating closed loop mesas.

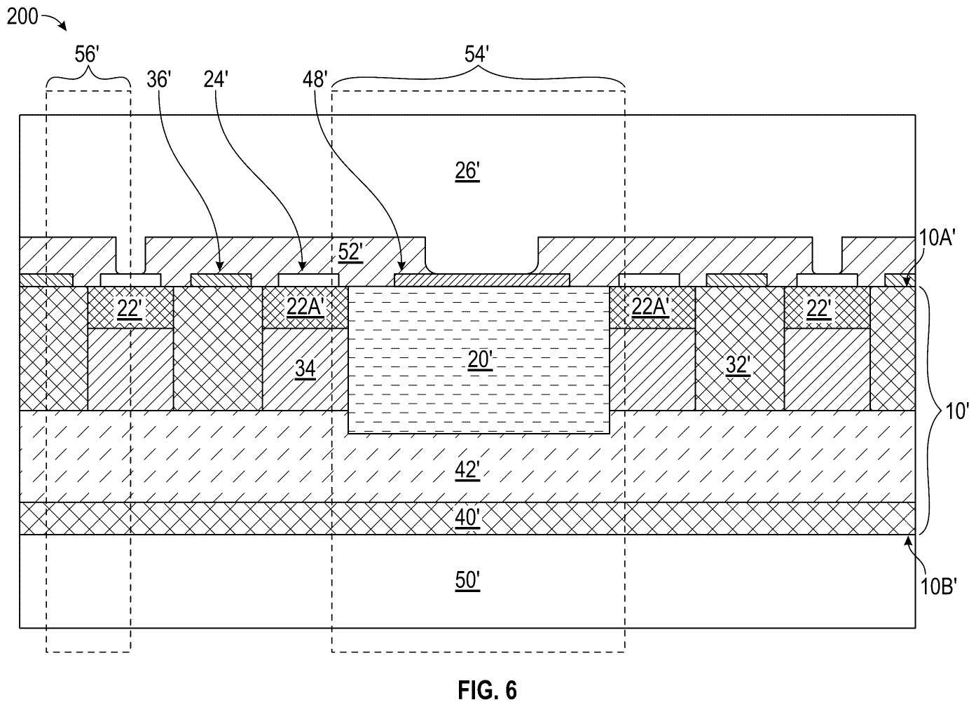

FIG. 6 is an exemplary cross-sectional view of a semiconductor die 200 having a source-drain anti-parallel diode cell 54′ integrated within vertical JFETs 56′ at a die level and according to an embodiment of the present disclosure. The semiconductor die 200 is substantially similar to the cross-sectional view of the semiconductor die 100 along a line B-B as shown in FIG. 1 and as described in FIG. 2, except that source regions 22′ and gate regions 32′ in the semiconductor die 200 are patterned alternatively in a substrate 10′. Other elements as previously described in reference to FIGS. 1-3 will continue to bear the same reference numerals as shown in FIGS. 1-3.

The semiconductor die 200 comprises the substrate 10′ having a top surface 10A′ and a bottom surface 10B′. A drain region 40′ extends from the bottom surface 10B′ into the substrate 10′ and is heavily doped with a first type dopant. A body region 42′ forms over above the drain region 40′ and is lightly doped with the first doping type and may further comprise other regions such as a drift region (not shown). The source regions 22′ are patterned under the top surface 10A′ of the substrate 10′. The source regions 22′ are heavily doped with the first doping type and extend from the top surface 10A′ into the substrate 10′ having a depth in the range of 0.1 μm to 2 μm, 0.1 μm to 1 μm, and 0.1 μm to 0.5 μm, and a width in the range of 0.1 μm to 10 μm, 0.5 μm to 5 μm, and 1 μm to 2 μm. Source ohmic contacts 24′ comprising silicide are disposed at least partially over top surfaces of the source regions 22′. In an embodiment, channel regions 34 form under the source regions 22′. The channel regions 34 are doped with the first doping type and extend vertically under the source regions 22′ as part of the body region 42′ and with a doping concentration in the range of 1e15 cm⁻³ to 5e18 cm⁻³, 5e15 cm⁻³ to 1e18 cm⁻³, and 1e16 cm⁻³ to 5e17 cm⁻³.

Next, the gate regions 32′ are patterned and form under the top surface 10A′ of the substrate 10′ and in between each of the two adjacent source regions 22′. The gate regions 32′ are doped with a second doping type that is the opposite type of the first doping type with a doping concentration in the range of 1e16 cm⁻³ to 1e22 cm⁻³, 1e17 cm⁻³ to 1e20 cm⁻³, and 1e18 cm⁻³ to 1e19 cm⁻³. Therefore, the gate regions 32′ extend from the top surface 10A′ into the substrate 10′ with a depth in the range of 0.1 μm to 10 μm, 0.5 μm to 3 μm, and 1 μm to 2 μm, and a width in the range of 0.1 μm to 10 μm, 0.5 μm to 5 μm, and 1 μm to 2 μm. Upon formation of the gate regions 32′, gate ohmic contacts 36′ that comprise of silicide are deposited over a top surface of the gate regions 32′.

The semiconductor die 200 further comprises an anode region 20′ that is a heavily doped region with the second type dopant. The anode region 20′ extends vertically downward from the top surface 10A′ into the substrate 10′ and in between two source ohmic regions 22A′ adjacent to the anode region 20′. In this regard, a doping concentration of the anode region 20′ is in the range of 1e16 cm⁻³ to 1e22 cm⁻³, 1e17 cm⁻³ to 1e20 cm⁻³, and 1e18 cm⁻³ to 1e19 cm⁻³. Furthermore, the anode region 20′ extends vertically into the substrate 10′, having a depth in the range of 0.1 μm to 10 μm, 0.5 μm to 3 μm, and 1 μm to 2 μm and a width in the range of 1 μm to 200 μm, 1.5 μm to 100 μm, and 2 μm to 20 μm. An anode ohmic contact 48′ is disposed over a top surface of the anode region 20′.

In an embodiment, the gate regions 32′ and the source regions 22′ have substantially similar widths. The anode region 20′ may be wider (i.e., have a larger surface area) and deeper than each of the gate regions 32′ and the source regions 22′. Next, an interlayer dielectric 52′ is disposed over the top surface of the substrate 10′ such that the gate ohmic contacts 36′, the source ohmic contacts 24′, and the anode ohmic contact 48′ are covered and isolated from one another. Portions of the interlayer dielectric 52′ over a top surface of the anode ohmic contact 48′ and top surfaces of the source ohmic contacts 24′ are removed, for example, by etching, except for the interlayer dielectric 52′ over the source ohmic contacts 24′ that are adjacent to the anode ohmic contact 48′. In this manner, contact windows formed over the top surfaces of the anode ohmic contact 48′ and the source ohmic contacts 24′ create an electrical contact path between the anode ohmic contact 48′ and, therefore, the anode region 20′ and the source ohmic contacts 24′, and therefore the source regions 22′, are formed. A source overlay metal 26′ is then deposited over a top surface of the interlayer dielectric 52′ and inside contact windows over top surface of the anode ohmic contact 48′ and the source ohmic contacts 24′. Lastly, through backside processes such as wafer thinning, drain contact formation, and backside metallization, a drain-cathode electrode 50′ is formed over a backside surface of the substrate 10′. In this manner, the source-drain anti-parallel diode cell 54′ forms within the vertical JFETs 56′. In various embodiments, the first dopant type may be a N dopant type and the second dopant type may be a P dopant type or vice versa.

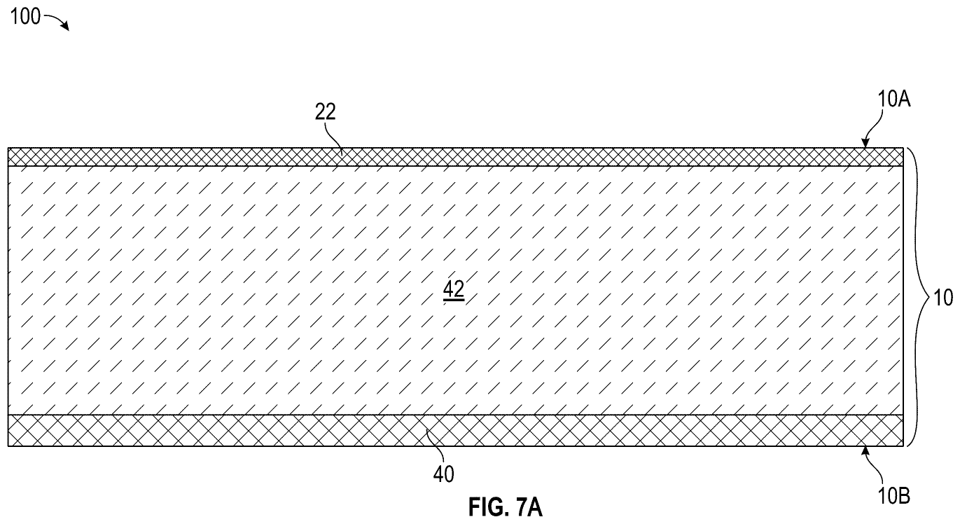

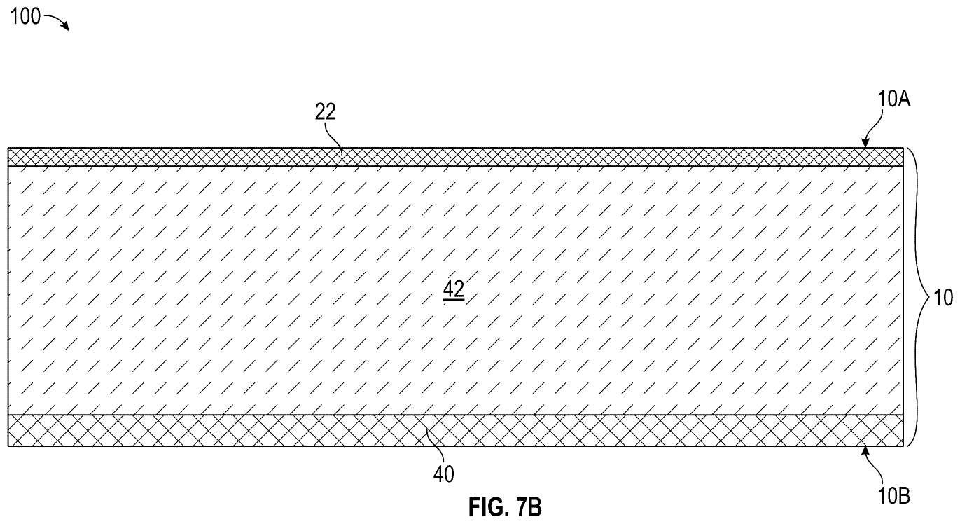

FIG. 7A illustrates a cross-sectional view of a substrate 10 as used in a fabrication of the semiconductor die 100 as shown in FIG. 1 along a line A-A. The substrate 10 has a top surface 10A and a bottom surface 10B and comprises a drain region 40, a body region 42, and a source region 22. The drain region 40 is a heavily doped region of the first doping type that extends from a bottom surface 10B of the substrate 10 into the substrate 10. A doping concentration of the drain region 40 is in the range of 1e18 cm⁻³ to 5e22 cm⁻³, 5e18 cm⁻³ to 1e22 cm⁻³, and 1e19 cm⁻³ to 1e21 cm⁻³. Furthermore, the drain region 40 may have a thickness in the range of 0.1 μm to 600 μm, 50 m to 500 μm, and 100 μm to 350 μm. The body region 42 forms within the substrate 10 and above the drain region 40 by epitaxy or other applicable methods and is doped with the first doping type. The body region 42 may have a doping concentration in the range of 1e14 cm⁻³ to 1e18 cm⁻³, 5e14 cm⁻³ to 5e17 cm⁻³, and 1e15 cm⁻³ to 1e17 cm⁻³ and may have a thickness in the range of 0.1 μm to 200 μm, 0.5 μm to 100 μm, and 1 μm to 60 μm. According to various embodiments of the present disclosure, the body region 42 may further comprise a channel region or a drift region that are not shown herein for the simplicity of the illustrations. The source region 22 is a heavily doped region of first doping type that extends from the top surface 10A of the substrate 10 into the substrate 10 and above the body region 42. In this regard, the source region 22 is doped with the first doping type with a doping concentration in the range of 1e17 cm⁻³ to 5e22 cm⁻³, 5e17 cm⁻³ to 1e22 cm⁻³, and 1e18 cm⁻³ to 1e21 cm⁻³. The source region 22 may be formed by epitaxy, implantation, or other applicable methods with a thickness in the range of 0.1 μm to 2 μm, 0.1 μm to 1 μm, and 0.1 μm to 0.5 μm, and which is used as a source contact.

FIG. 7B illustrates a cross-sectional view of a substrate 10 as used in a fabrication of the semiconductor die 100 as shown in FIG. 1 along a line B-B. The substrate 10 has a top surface 10A and a bottom surface 10B and comprises a drain region 40, a body region 42, and a source region 22. The drain region 40 is a heavily doped region of the first doping type that extends from a bottom surface 10B of the substrate 10 into the substrate 10. A doping concentration of the drain region 40 is in the range of 1e18 cm⁻³ to 5e22 cm⁻³, 5e18 cm⁻³ to 1e22 cm⁻³, and 1e19 cm⁻³ to 1e21 cm⁻³. Furthermore, the drain region 40 may have a thickness in the range of 0.1 μm to 600 μm, 50 m to 500 μm, and 100 μm to 350 μm. The body region 42 forms within the substrate 10 and above the drain region 40 by epitaxy or other applicable methods and is doped with the first doping type. The body region 42 may have a doping concentration in the range of 1e14 cm⁻³ to 1e18 cm⁻³, 5e14 cm⁻³ to 5e17 cm⁻³, and 1e15 cm⁻³ to 1e17 cm⁻³ and may have a thickness in the range of 0.1 μm to 200 μm, 0.5 μm to 100 μm, and 1 μm to 60 μm. According to various embodiments of the present disclosure, the body region 42 may further comprise a channel region or a drift region that are not shown herein for the simplicity of the illustrations. The source region 22 is a heavily doped region of first doping type that extends from the top surface 10A of the substrate 10 into the substrate 10 and above the body region 42. In this regard, the source region 22 is doped with the first doping type with a doping concentration in the range of 1e17 cm⁻³ to 5e22 cm⁻³, 5e17 cm⁻³ to 1e22 cm⁻³, and 1e18 cm⁻³ to 1e21 cm⁻³. The source region 22 may be formed by epitaxy, implantation, or other applicable methods with a thickness in the range of 0.1 μm to 2 μm, 0.1 μm to 1 μm, and 0.1 μm to 0.5 μm, and which is used as a source contact.

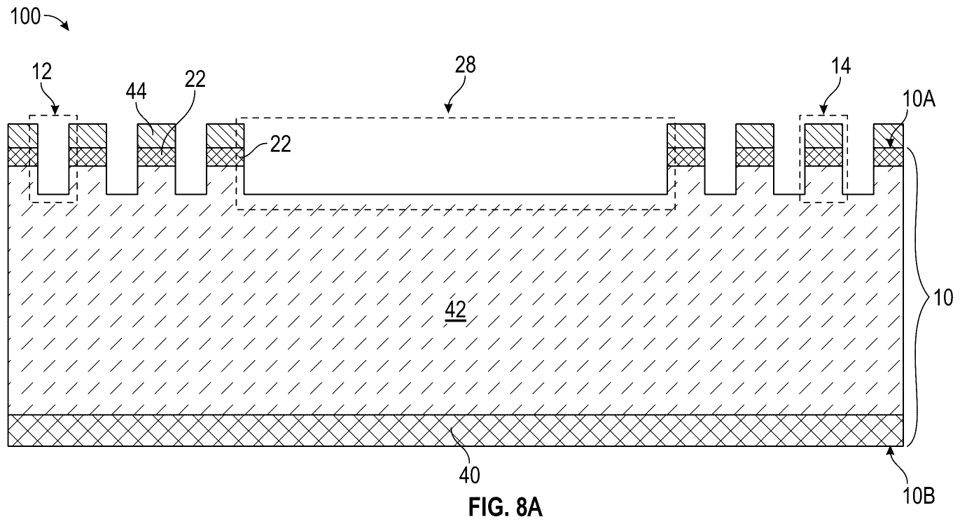

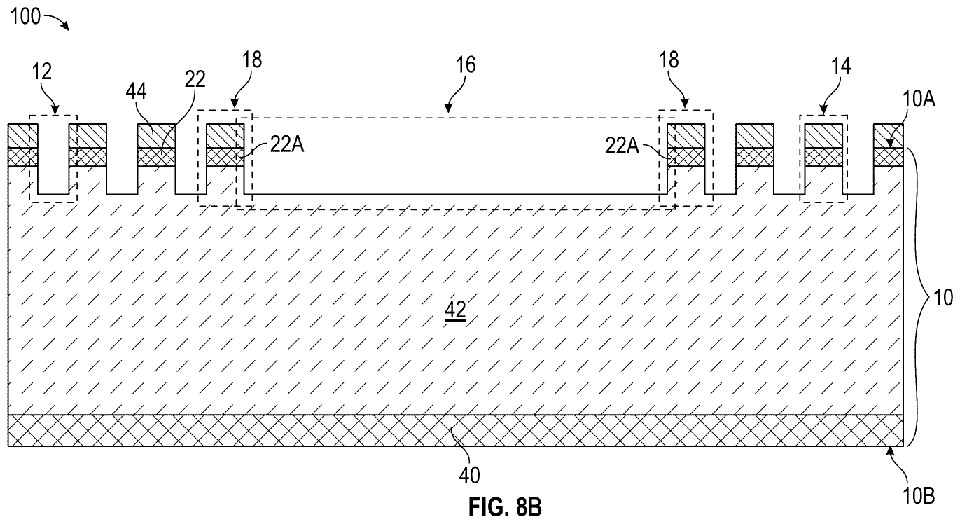

FIG. 8A illustrates a cross-sectional view of a substrate 10 as seen after trenches 12 and a gate contact window 28 are etched as part of a fabrication process of the semiconductor die 100 in FIG. 1 along a line A-A. To create the structure shown, a hard masking layer 44 is deposited over a top surface 10A of the substrate 10 and on top of the heavily doped source region 22 as shown in FIG. 7A. The hard masking layer 44 may be an oxide, a metal, both, or another suitable material. Next, the hard masking layer 44 is patterned using a mask (not shown), and the top surface 10A of the substrate 10 is etched to form the gate contact window 28 and a plurality of trenches, such as the trench 12, hereinafter collectively referred to as the trenches 12. In an embodiment, the trenches 12 extend downward from the top surface 10A into the substrate 10. In this manner, the trenches 12 extend from the top surface 10A into the source region 22 and the body region 42 and form a series of mesas, such as a mesa 14, hereinafter collectively referred to as the mesas 14. Similarly, the gate contact window 28 extends downward from the top surface 10A of the substrate 10 into the source region 22 and the body region 42.

The etching process leaves portions of the source region 22, hereinafter collectively referred to as the source regions 22, over top surfaces of the mesas 14. In an embodiment, each of the trenches 12 may extend into the substrate 10 with a substantially similar depth to one another in the range of 0.1 μm to 10 μm, 0.5 μm to 3 μm, and 1 μm to 2 μm. Furthermore, the trenches 12 may have a substantially similar opening to one another over the top surface 10A of the substrate 10 that is in the range of 0.1 μm to 10 μm, 0.5 μm to 5 μm, and 1 μm to 2 μm. It is to be noted that number, shape, and dimensions of the trenches 12 may vary according to various embodiments and is not limited to those shown in FIG. 8B. The gate contact window 28 may have a similar or a different depth from that of the trenches 12. The opening width of the gate contact window 28 may vary but is in the range of 1 μm to 1000 μm, 200 μm to 300 μm, and 400 μm to 600 μm along the line A-A as shown in FIG. 1. It is important to note that the position, shape, and/or number of the gate contact windows 28 forming part of the semiconductor die 100 may vary and that the scope of the present disclosure is not so limited and can be changed in various ways without departing from the scope of the present disclosure. All other elements as shown in FIG. 8A that were not discussed in relation to FIG. 8A were previously described in reference to FIGS. 1-3 and FIG. 7A. Said elements will continue to bear the same reference numerals and description as those previously provided in FIGS. 1-3 and FIG. 7A.

FIG. 8B illustrates a cross-sectional view of a substrate 10 as seen after trenches 12 and an anode trench 16 are etched as part of a fabrication process of a semiconductor die 100 in FIG. 1 along a line B-B. To create the structure shown, a hard masking layer 44 is deposited over a top surface 10A of the substrate 10 and on top of the heavily doped source region 22 as shown in FIG. 7B. The hard masking layer 44 may be an oxide, a metal, both, or any other suitable material. Next, the hard masking layer 44 is patterned using a mask (not shown), and the top surface 10A of the substrate 10 is etched to form the anode trench 16 and a plurality of trenches, such as the trench 12, hereinafter collectively referred to as the trenches 12. In an embodiment, the trenches 12 extend downward from the top surface 10A of the substrate 10 and into the source region 22 and the body region 42 to form a series of mesas, such as a mesa 14, hereinafter collectively referred to as the mesas 14. Similarly, the anode trench 16 extends downward from the top surface 10A of the substrate 10 into the source region 22 and the body region 42 in between two floating closed loop mesas 18 that form part of a single element, the floating closed loop mesa 18 surrounding the anode trench 16 as shown in FIG. 1.

The etching process leaves portions of the source region 22, hereinafter collectively referred to as the source regions 22, over top surfaces of the mesas 14 and under remaining portions of the hard masking layer 44. Furthermore, floating source regions 22A remain over top surfaces of the floating closed loop mesas 18 adjacent to the anode trench 16. In an embodiment, each of the trenches 12 may extend into the substrate 10 with a substantially similar depth to one another in the range of 0.1 μm to 10 μm, 0.5 μm to 3 μm, and 1 μm to 2 μm. Therefore, and according to various embodiments, the anode trench 16 of the diode cell 54 may be 0.1 μm to 1 μm deeper than the trenches 12 of vertical JFETs 56. The trenches 12 may have a substantially similar opening to one another over the top surface 10A of the substrate 10 that is in the range of 0.1 μm to 10 μm, 0.5 μm to 5 μm, and 1 μm to 2 μm. It is to be noted that the number of the trenches 12 may vary according to various embodiments and is not limited to those shown in FIG. 7B. The anode trench 16 may have a similar or a different depth from that of the trenches 12. The anode trench 16 may have an opening over the top surface 10A of the substrate 10 along the line B-B, as shown in FIG. 1, that is in the range of 1 μm to 200 μm, 1.5 μm to 100 μm, and 2 μm to 20 μm. As with the trenches 12, it is to be noted that more than one anode trench 16 may form part of the semiconductor die 100, along the line B-B in FIG. 1 or elsewhere over a surface of the substrate 10, in accordance with various embodiments of the present disclosure. Therefore, the number of the anode trenches 16 is not limited to that shown in FIG. 8B.

In an embodiment, the surface area of the bottom surface of the anode trench 16 may be larger than those of the trenches 12. Alternatively, or in addition, the anode trench 16 may be etched at a higher etch rate and therefore form a deeper trench compared with the trenches 12 in the vertical JFETs 56. Increasing the surface area and/or depth of the anode trench 16 in relation to the trenches 12 is advantageous in that it allows the diode cell 54 to have a lower breakdown voltage (BV_{GD}) than the vertical JFETs 56, enabling the diode cell 54 to serve as an avalanche clamp.

It is to be noted that all other elements as shown in FIG. 8B that were not discussed in relation to FIG. 8B were previously described in reference to FIGS. 1-3 and FIG. 7B. Said elements will continue to bear the same reference numerals and description as those previously provided in FIGS. 1-3 and FIG. 7B.

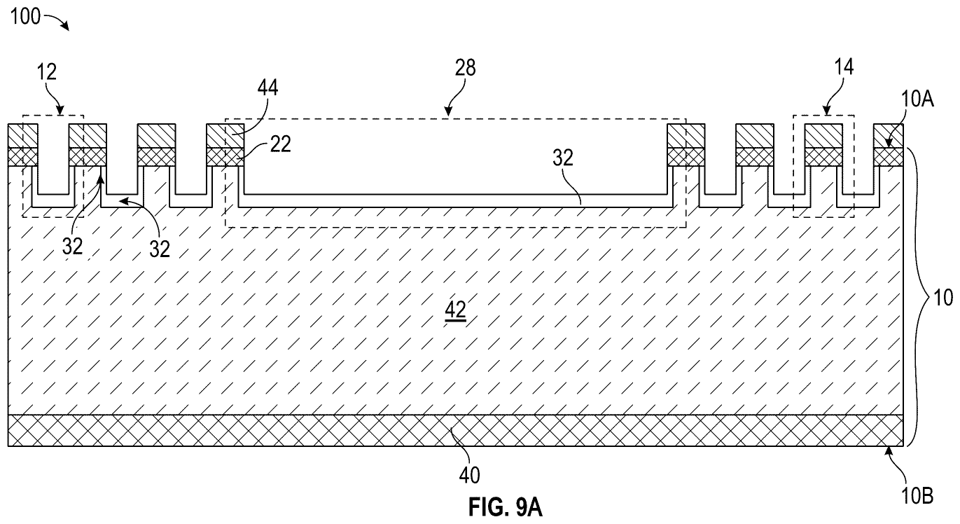

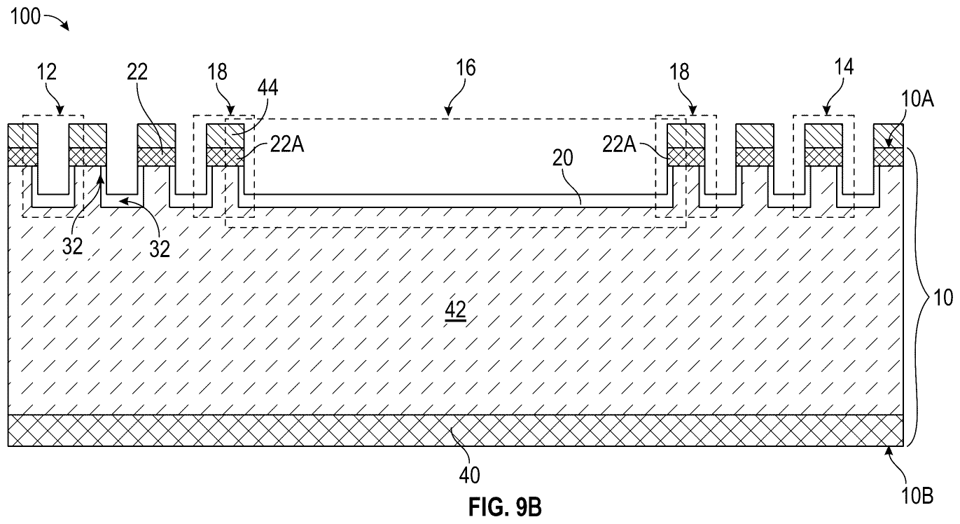

FIG. 9A illustrates a cross-sectional view of a substrate 10 as seen after implantations of a first doping type as part of a fabrication process of the semiconductor die 100 in FIG. 1 along a line A-A. The implantations are performed without removing the hard masking layer 44 in FIG. 8A and FIG. 8B. No additional masks are needed for this step. A vertical implantation of a second doping type forms gate regions 32 under bottom surfaces of trenches 12, with a doping concentration in the range of 1e16 cm⁻³ to 1e22 cm⁻³, 1e17 cm⁻³ to 1e20 cm⁻³, and 1e18 cm⁻³ to 1e19 cm⁻³ and a thickness in the range of 0.1 μm to 5 μm, 0.2 μm to 2 μm, or 0.5 μm to 1 μm that extend downward under bottom surfaces of the trenches 12. Furthermore, the vertical implantation of the second doping type forms a part of the gate region 32 under a bottom surface of a gate contact window 28, with a doping concentration and a thickness that may be substantially similar to or different from that of the gate regions 32 under the bottom surfaces of the trenches 12.

The hard masking layer 44 protects source regions 22 from being counter-doped by the implantation. A tilted implantation of the second doping type is used to form the gate regions 32 on side walls of the trenches 12 and on side walls of the gate contact window 28. The gate regions 32 are formed on side walls of the trenches 12 and on side walls of the gate contact window 28 may optionally be less-heavily doped than the gate regions 32 formed at the bottoms of the trenches 12 and the gate contact window 28. The hard mask 44 is removed after implantations are completed. Next, the substrate 10 is annealed to activate the implanted dopants. It is noted that all other elements as shown in FIG. 9A that were not discussed in relation to FIG. 9A were previously described in reference to FIGS. 1-3, FIG. 7A, and FIG. 8A. Said elements will continue to bear the same reference numerals and description as those previously provided in reference to FIGS. 1-3, FIG. 7A, and FIG. 8A.

FIG. 9B illustrates a cross-sectional view of a substrate 10 as seen after implantations of a first doping type as part of a fabrication process of the semiconductor die 100 in FIG. 1 along a line B-B. The implantations are performed without removing the hard masking layer 44 in FIG. 8A and FIG. 8B. No additional masks are needed for this step. A vertical implantation of a second doping type forms gate regions 32 under bottom surfaces of trenches 12 and an anode region 20 under a bottom surface of an anode trench 16, with a doping concentration in the range of 1e16 cm⁻³ to 1e22 cm⁻³, 1e17 cm⁻³ to 1e20 cm⁻³, and 1e18 cm⁻³ to 1e19 cm⁻³. Therefore, the gate regions 32 under bottom surfaces of the trenches 12 and the anode region 20 under the bottom surface of the anode trench 16 may have a substantially similar thickness in the range of 0.1 μm to 5 μm, 0.2 μm to 2 μm, or 0.5 μm to 1 μm that extend downward under the bottom surfaces of the trenches 12 and the anode trench 16, respectively. According to various embodiments, doping concentrations and/or thicknesses of the gate regions 32 under the bottom surfaces of the trenches 12 and the anode region 20 may be substantially the same or vary. The hard masking layer 44 protects source regions 22 from being counter-doped by the implantation. A tilted implantation of the second doping type is used to form the gate regions 32 behind side walls of the trenches 12. The gate regions 32 formed on side walls of the trenches 12 may optionally be less heavily doped than the gate regions 32 formed at bottoms of the trenches 12. In certain embodiments, the tilted implantation of the second doping type forms and the anode region 20 behind side walls of the anode trench 16. The hard mask 44 is removed after implantations are completed. Next, the substrate 10 is annealed to activate the implanted dopants. It is noted that all other elements as shown in FIG. 9B that were not discussed in relation to FIG. 9B were previously described in reference to FIGS. 1-3, FIG. 7B, and FIG. 8B. Said elements will continue to bear the same reference numerals and description as those previously provided in reference to FIGS. 1-3, FIG. 7B, and FIG. 8B.

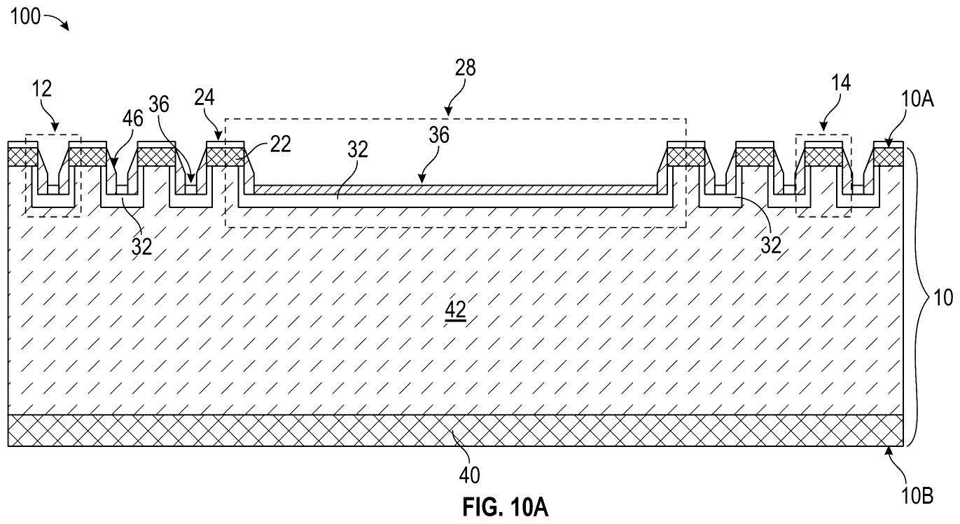

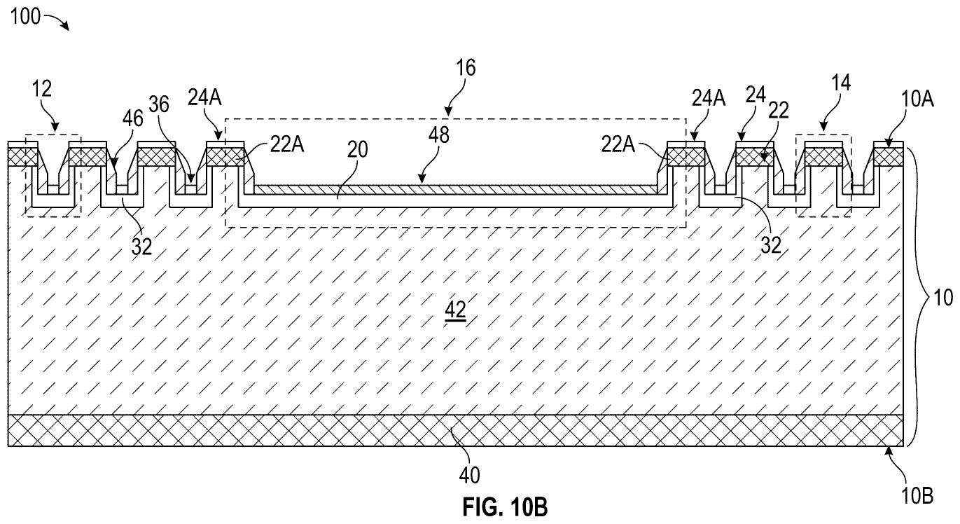

FIG. 10A illustrates a cross-sectional view of a substrate 10 as seen after self-aligned silicide contacts form as a part of a fabrication process of the semiconductor die 100 in FIG. 1 along a line A-A. To form gate ohmic contacts 36 over gate regions 32, oxide spacers 46 are formed by depositing and/or growing oxide on sidewalls of trenches 12 and a gate contact window 28, followed by an etching process that operates primarily vertically such that the oxide spacers 46 remain only on the sidewalls of the trenches 12 and the gate contact window 28. Next, an ohmic metal, for example nickel (Ni), or any other suitable metal, is deposited over top surfaces of source regions 22, bottom surfaces of the trenches 12, a bottom surface of the gate contact window 28, and over exposed portions of the gate regions 32, and is annealed using rapid thermal annealing to form silicide, such as source ohmic contacts 24 and the gate ohmic contacts 36, respectively. Any unreacted ohmic metal remaining on the oxide spacers 46 is subsequently removed such that the source ohmic contacts 24 and the gate ohmic contacts 36 remain electrically isolated. All other elements as shown in FIG. 10A that are not discussed in relation to FIG. 10A were previously described in reference to FIGS. 1-3 and FIGS. 7A-9A. Said elements will continue to bear the same reference numerals and description as those previously provided in reference FIGS. 1-3 and FIGS. 7A-9A.

FIG. 10B illustrates a cross-sectional view of a substrate 10 as seen after self-aligned silicide contacts formation as part of a fabrication process of the semiconductor die 100 in FIG. 1 along a line B-B. As shown, gate regions 32 that are U-shaped are formed under bottom surfaces and behind portions of sidewalls of trenches 12 under source regions 22. To form gate ohmic contacts 36 over the gate regions 32 at the bottom surfaces of the trenches 12, oxide spacers 46 are formed by depositing and/or growing oxide on the sidewalls of the trenches 12 followed by an etching process that operates primarily vertically such that the oxide spacers 46 remain only on the sidewalls of the trenches 12. Next, an ohmic metal, for example nickel (Ni) or any other suitable metal, is deposited over top surfaces of the source regions 22, top surface of the floating source regions 22A, the bottom surfaces of the trenches 12 over exposed portions of the gate regions 32, and a bottom surface of an anode trench 16 over a top surface of an anode region 20, and is annealed using rapid thermal annealing to form silicide such as source ohmic contacts 24, floating source ohmic contacts 24A, the gate ohmic contact 36, and an anode ohmic contact 48, respectively. Any unreacted ohmic metal remaining on the oxide spacers 46 is subsequently removed such that the source ohmic contacts 24 and the gate ohmic contacts 36 remain electrically isolated. All other elements as shown in FIG. 10B that are not discussed in relation to FIG. 10B were previously described in reference to FIGS. 1-3 and FIGS. 7B-9B. Said elements will continue to bear the same reference numerals and description as those previously provided in reference FIGS. 1-3 and FIGS. 7B-9B.

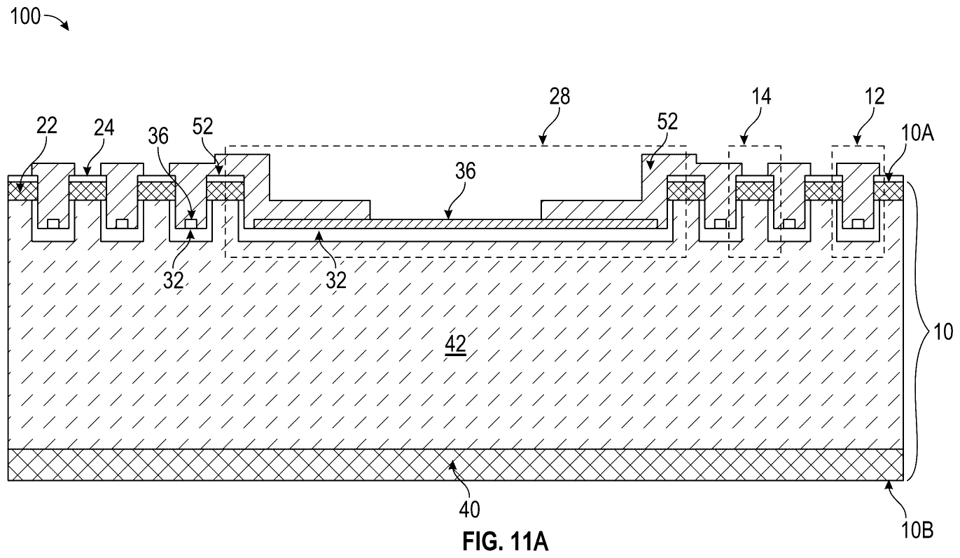

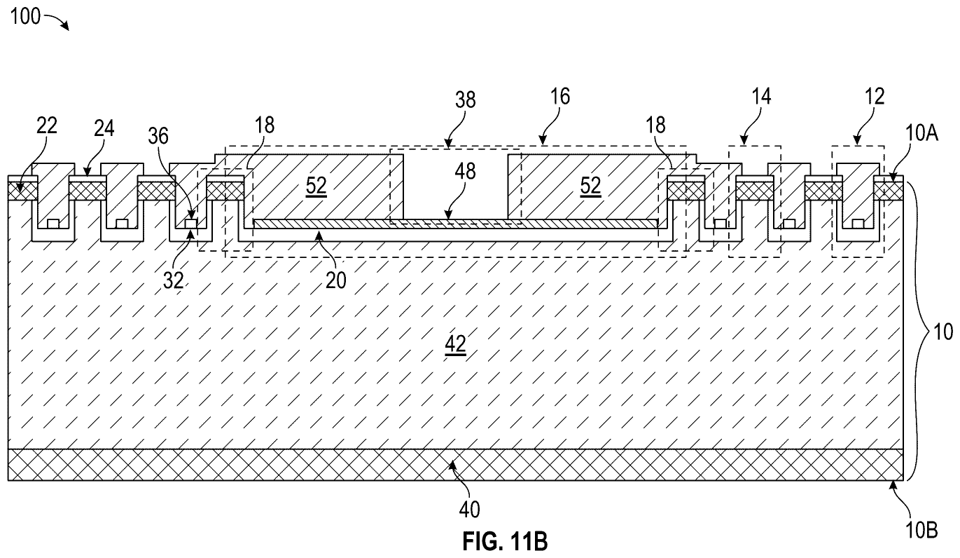

FIG. 11A illustrates a cross-sectional view of a substrate 10 as seen after a contact window opens using a mask as a part of a fabrication process of the semiconductor die 100 in FIG. 1 along a line A-A. First, an interlayer dielectric 52, such as oxide, or the like, is deposited over a topmost surface of the substrate 10, filling trenches 12 and a gate contact window 28 and covering top surfaces of mesas 14. Next, a mask (not shown) is used to pattern contact openings to source ohmic contacts 24 over the mesas 14 and the top surface of a gate ohmic contact 36. Contact openings are formed through an etching process. All other elements as shown in FIG. 11A that are not discussed in relation to FIG. 11A were previously described in reference to FIGS. 1-3 and FIGS. 7A-10A. Said elements will continue to bear the same reference numerals and description as those previously provided in reference to FIGS. 1-3 and FIGS. 7A-10A.

FIG. 11B illustrates a cross-sectional view of a substrate 10 as seen after a contact window opens using a mask as part of a fabrication process of the semiconductor die 100 in FIG. 1 along a line B-B. First, an interlayer dielectric 52, such as oxide, or any other suitable material, is deposited over a topmost surface of the substrate 10, filling trenches 12 and an anode trench 16 and covering top surfaces of mesas 14 and surfaces of floating closed loop mesas 18. Next, a mask (not shown) is used to pattern contact openings to source ohmic contacts 24 over the top surfaces of the mesas 14 and to form a via 38 over a portion of the top surface of an anode ohmic contact 48. Contact openings to the source ohmic contacts 24 over the mesas 14 and the via 38 are formed through an etching process. It is important to note that the interlayer dielectric 52 over the floating closed loop mesas 18 is not removed such that the source ohmic contacts 24 over the floating closed loop mesas 18 remain electrically isolated and floating. All other elements as shown in FIG. 11B that are not discussed in relation to FIG. 11B were previously described in reference to FIGS. 1-3 and FIGS. 7B-10B. Said elements will continue to bear the same reference numerals and description as those previously provided in reference to FIGS. 1-3 and FIGS. 7B-10B.

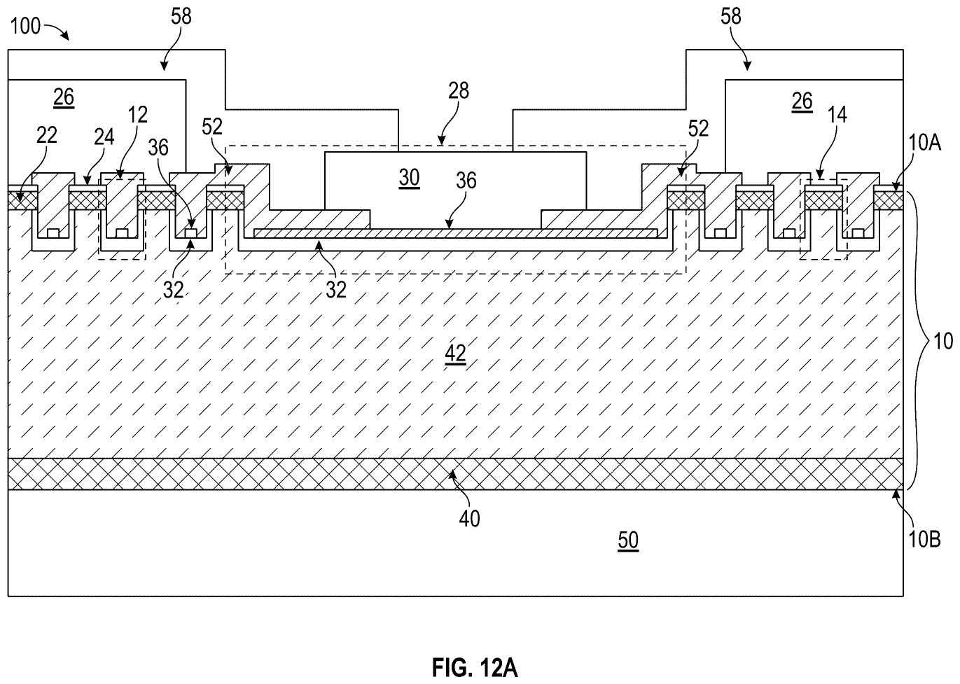

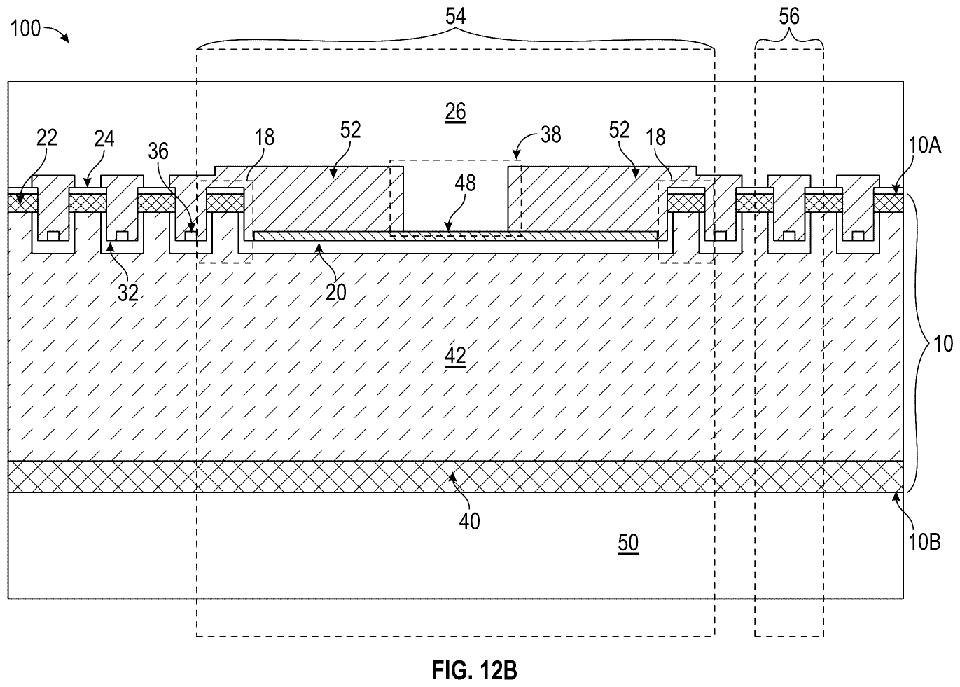

FIG. 12A illustrates a cross-sectional view of a substrate 10 as seen after an overlay metal is deposited using a mask as part of a fabrication process of the semiconductor die 100 in FIG. 1 along a line A-A. A conductor such as a metal is deposited, patterned using a mask, and etched, leaving a source overlay metal 26 and a gate overlay metal 30 separated by a passivation layer 58. The source overlay metal 26 makes contact and electrically connects to source ohmic contacts 24 and thereby to source regions 22. The gate overlay metal 30 makes contact to gate ohmic contacts 36 and thereby to gate regions 32. Lastly, through backside processes such as wafer thinning, drain contact formation, and backside metallization, a drain-cathode electrode 50 is formed over a backside surface of the substrate 10. All other elements as shown in FIG. 12A that are not discussed in relation to FIG. 12A were previously described in reference to FIGS. 1-3 and FIGS. 7A-11A. Said elements will continue to bear the same reference numerals and description as those previously provided in reference to FIGS. 1-3 and FIGS. 7A-11A.

FIG. 12B illustrates a cross-sectional view of a substrate 10 as seen after an overlay metal is deposited as part of a fabrication process of the semiconductor die 100 in FIG. 1 along a line B-B. A conductor such as a metal is deposited, patterned using a mask, and etched, leaving a source overlay metal 26 and a gate overlay metal 30 (as shown in FIG. 12A). The source overlay metal 26 makes contact and electrically connects to source ohmic contacts 24 and thereby to source regions 22. Lastly, through backside processes such as wafer thinning, drain contact formation, and backside metallization, a drain-cathode electrode 50 is formed over a bottom surface 10B of the substrate 10. In this manner, a diode cell 54 forms within vertical JFETs 56. All other elements as shown in FIG. 12B that are not discussed in relation to FIG. 12B were previously described in reference to FIGS. 1-3 and FIGS. 7B-11B. Said elements will continue to bear the same reference numerals and description as those previously provided in reference to FIGS. 1-3 and FIGS. 7B-11B.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A semiconductor die, comprising:
a substrate having a top surface and a bottom surface;
a drain-cathode region extending from the bottom surface into the substrate;
a plurality of trenches, wherein each of the plurality of trenches extends from the top surface into the substrate;
a plurality of mesas, wherein each of the plurality of the mesas resides between adjacent ones of the plurality of trenches;
a first anode trench extending from the top surface into the substrate forming a contiguous region to a first two or more of the plurality of trenches;
a first floating closed loop mesa surrounding the first anode trench and in between a first two or more of the plurality of mesas;
a first anode region under the first anode trench;
a plurality of source regions, wherein each of the plurality of source regions extends from the top surface into each of the plurality of mesas;
a plurality of gate regions, wherein each of the plurality of gate regions extends along bottom surfaces and portions of sidewalls of each of the plurality of trenches; and
wherein the first floating closed loop mesa electrically isolates the first anode region from the plurality of gate regions, and the first anode region and the plurality of source regions are electrically coupled to form a first anti-parallel diode cell integrated within vertical junction field-effect transistors (JFETs).

2. The semiconductor die of claim 1, further comprising a first floating source region extending from the top surface into the first floating closed loop mesa, and a first floating source ohmic contact at least partially over a top surface of the first floating source region.

3. The semiconductor die of claim 2, further comprising a plurality of gate ohmic contacts at least partially over the plurality of gate regions at the bottom surfaces of the plurality of trenches, a first anode ohmic contact at least partially over a top surface of the first anode region, and a plurality of source ohmic contacts at least partially over top surfaces of the plurality of source regions.

4. The semiconductor die of claim 3, further comprising an interlayer dielectric filling the plurality of trenches and the first anode trench and covering surfaces of the first floating closed loop mesa to electrically isolate the first anode region from the plurality of gate regions.

5. The semiconductor die of claim 4, further comprising a first via hole in the interlayer dielectric in the first anode trench.

6. The semiconductor die of claim 5, further comprising a source overlay metal over and electrically coupled to the plurality of source ohmic contacts and in the first via hole and electrically coupled to the first anode ohmic contact.

7. The semiconductor die of claim 6, further comprising a gate overlay metal electrically coupled to the plurality of gate ohmic contacts.

8. The semiconductor die of claim 7, further comprising a drain-cathode electrode over the bottom surface of the substrate and electrically coupled to the drain-cathode region.

9. The semiconductor die of claim 1, further comprising:
a second anode trench extending from the top surface into the substrate forming a contiguous region to a second two or more of the plurality of trenches;
a second floating closed loop mesa surrounding the second anode trench and in between a second two or more of the plurality of mesas; and a second anode region under the second anode trench; and
wherein the second floating closed loop mesa electrically isolates the second anode region from the plurality of gate regions, and the second anode region and the plurality of source regions are electrically coupled to form a second anti-parallel diode cell integrated within the vertical JFETs.

10. The semiconductor die of claim 9, further comprising a first floating source region extending from the top surface into the first floating closed loop mesa, a second floating source region extending from the top surface into the second floating closed loop mesa, a first floating source ohmic contact at least partially over a top surface of the first floating source region, and a second floating source ohmic contact at least partially over a top surface of the second floating source region.

11. The semiconductor die of claim 10, further comprising a plurality of gate ohmic contacts at least partially over the plurality of gate regions at the bottom surfaces of the plurality of trenches, a first anode ohmic contact at least partially over a top surface of the first anode region, a second anode ohmic contact at least partially over a top surface of the second anode region, and a plurality of source ohmic contacts at least partially over top surfaces of the plurality of source regions.

12. The semiconductor die of claim 11, further comprising an interlayer dielectric filling the plurality of trenches, the first anode trench, and the second anode trench, covering surfaces of the first floating closed loop mesa to electrically isolate the first anode region from the plurality of gate regions, and covering surfaces of the second floating closed loop mesa to electrically isolate the second anode region from the plurality of gate regions.

13. The semiconductor die of claim 12, further comprising a first via hole in the interlayer dielectric in the first anode trench and a second via hole in the interlayer dielectric in the second anode trench.

14. The semiconductor die of claim 13, further comprising a source overlay metal over and electrically coupled to the plurality of source ohmic contacts, in the first via hole to electrically couple to the first anode ohmic contact, and the second via hole to electrically couple to the second anode ohmic contact.

15. The semiconductor die of claim 14, further comprising a gate overlay metal electrically coupled to the plurality of gate ohmic contacts.

16. The semiconductor die of claim 15, further comprising a drain-cathode electrode over the bottom surface of the substrate and electrically coupled to the drain-cathode region.

17. The semiconductor die of claim 1, further comprising a third floating closed loop mesa over the top surface of the substrate surrounding the first floating closed loop mesa and a first floating trench between the third floating closed loop mesa and the first floating closed loop mesa.

18. The semiconductor die of claim 17, further comprising a first floating source region extending from the top surface into the first floating closed loop mesa and a third floating source region extending from the top surface into the third floating closed loop mesa, and a first floating gate region extending along bottom surfaces and portions of sidewalls of the first floating trench.

19. The semiconductor die of claim 18, further comprising a first floating source ohmic contact at least partially over a top surface of the first floating source region, a third floating source ohmic contact at least partially over a top surface of the third floating source region, and a floating gate ohmic contact at least partially over a top surface of the first floating gate region.

20. The semiconductor die of claim 19, further comprising a plurality of gate ohmic contacts at least partially over the plurality of gate regions at the bottom surfaces of the plurality of trenches, a first anode ohmic contact at least partially over a top surface of the first anode region, and a plurality of source ohmic contacts at least partially over top surfaces of the plurality of source regions.

21. The semiconductor die of claim 20, further comprising an interlayer dielectric filling the plurality of trenches, the first floating trench, and the first anode trench, and covering surfaces of the first floating closed loop mesa and the third floating closed loop mesa to electrically isolate the first anode region from the plurality of gate regions.

22. The semiconductor die of claim 21, further comprising a first via hole in the interlayer dielectric in the first anode trench.

23. The semiconductor die of claim 22, further comprising a source overlay metal over and electrically coupled to the plurality of source ohmic contacts and in the first via hole and electrically coupled to the first anode ohmic contact.

24. The semiconductor die of claim 23, further comprising a gate overlay metal electrically coupled to the plurality of gate ohmic contacts.

25. The semiconductor die of claim 24, further comprising a drain-cathode electrode over the bottom surface of the substrate and electrically coupled to the drain-cathode region.

26. The semiconductor die of claim 1, wherein the substrate comprises silicon carbide.

27. The semiconductor die of claim 1, wherein the substrate comprises gallium nitride (GaN), aluminum nitride (AlN), gallium (III) oxide (Ga₂O₃), or diamond.

28. The semiconductor die of claim 1, wherein the first anode trench and the plurality of trenches have a same depth.

29. The semiconductor die of claim 1, wherein the first anode trench is deeper than each of the plurality of trenches.

30. The semiconductor die of claim 1, wherein bottom surfaces of the first anode trench and the bottoms surfaces of the plurality of trenches have a same surface area.

31. The semiconductor die of claim 1, wherein a bottom surface of the first anode trench has a larger surface area than the bottom surfaces of each of the plurality of trenches.

32. The semiconductor die of claim 1 wherein the plurality of gate regions and the first anode region are doped with a p-type dopant, and a remaining portion of a body region and the substrate are doped with an n-type dopant.

33. The semiconductor die of claim 1 wherein the plurality of gate regions and the first anode region are doped with an n-type dopant, and a remaining portion of a body region and the substrate are doped with a p-type dopant.

34. A method of fabricating a semiconductor device, comprising:
providing a substrate having a top surface and a bottom surface;
forming a drain-cathode region extending from the bottom surface into the substrate;
forming a plurality of trenches, wherein each of the plurality of trenches extends from the top surface into the substrate;
forming a plurality of mesas, wherein each of the plurality of the mesas resides between adjacent ones of the plurality of trenches;
forming a first anode trench extending from the top surface into the substrate and contiguous to a first two or more of the plurality of trenches;
forming a first floating closed loop mesa surrounding the first anode trench and in between a first two or more of the plurality of mesas;
forming a first anode region under the first anode trench;
forming a plurality of source regions, wherein each of the plurality of source regions extends from the top surface into each of the plurality of mesas;
forming a plurality of gate regions, wherein each of the plurality of gate regions extends along bottom surfaces and portions of sidewalls of each of the plurality of trenches; and
wherein the first floating closed loop mesa electrically isolates the first anode region from the plurality of gate regions, and the first anode region and the plurality of source regions are electrically coupled to form a first anti-parallel diode cell integrated within vertical junction field-effect transistors (JFETs).
